(19) United States
(12) Patent Application Publication
(10) Pub. No.: US 2017/0294548 A1
(43) Pub. Date: Oct. 12, 2017

(54) INSULATION PASTE, METHOD FOR MANUFACTURING SOLAR CELL ELEMENT AND SOLAR CELL ELEMENT

(71) Applicant: KYOCERA CORPORATION, Kyoto (JP)

(72) Inventors: Jumpei SATO, Ritto-shi (JP); Ryo MATSUOKA, Ritto-shi (JP); Shinya ISHIKAWA, Higashiomi-shi (JP)

(21) Appl. No.: 15/484,881

(22) Filed: Apr. 11, 2017

(30) Foreign Application Priority Data
Apr. 12, 2016 (JP) 2016-079806
Apr. 11, 2017 (JP) 2017-077981

(51) Int. Cl. H01L 31/048; H01L 31/0236; H01L 31/18; H01L 31/0216

(52) U.S. Cl. CPC H01L 31/0481; H01L 31/02167; H01L 31/02363; H01L 31/1868

(57) ABSTRACT

An insulating paste includes a siloxane resin and an organic solvent. The siloxane resin includes a phenyl group and an alkyl group expressed by a general formula CₙH₂ₙ₊₁, in which n is a natural number. The number of alkyl groups is greater than the number of phenyl groups in the siloxane resin.

### CROSS-REFERENCE TO RELATED APPLICATIONS

The present application claims priority under 35 U.S.C. §119 to Japanese Patent Application No. 2016-079806, filed on Apr. 12, 2016, entitled “INSULATING PASTE AND METHOD OF MANUFACTURING SOLAR CELL DEVICE” and to Japanese Patent Application No. 2017-077981, filed on Apr. 11, 2017, entitled “INSULATING PASTE, METHOD OF MANUFACTURING SOLAR CELL DEVICE, AND SOLAR CELL DEVICE”. The contents of these applications are incorporated herein by reference in their entirety.

### FIELD

The present disclosure relates to an insulating paste, a method of manufacturing a solar cell device, and a solar cell device.

### BACKGROUND

Passivated emitter and rear cell (PERC) solar cell devices that each includes, at a rear-surface side thereof, a semiconductor substrate, a passivation layer located on the surface of the semiconductor substrate, and a dielectric layer located on the passivation layer to protect the passivation layer have been proposed.

### SUMMARY

An insulating paste, a method of manufacturing a solar cell device, and a solar cell device are disclosed.

In one aspect, the insulating paste includes a siloxane resin and an organic solvent. The siloxane resin includes a phenyl group and an alkyl group expressed by a general formula CₙH₂ₙ₊₁, in which n is a natural number. The number of alkyl groups is greater than the number of phenyl groups in the siloxane resin.

In one aspect, the method of manufacturing the solar cell device includes: forming a passivation layer on a semiconductor substrate; applying the above-mentioned insulating paste onto the passivation layer; and firing the insulating paste to thereby form a protective layer on the passivation layer.

In one aspect, the solar cell device includes a semiconductor substrate, a passivation layer, and a protective layer. The semiconductor substrate includes a p-type semiconductor region in a surface thereof. The passivation layer is located on the p-type semiconductor region, and includes an aluminum oxide. The protective layer is located on or above the passivation layer, and includes a silicon oxide. The protective layer includes at least one double bond selected from the group consisting of a carbon-oxygen double bond, a carbon-carbon double bond, and a carbon-nitrogen double bond.

### BRIEF DESCRIPTION OF THE DRAWINGS

FIG. 1 illustrates an example of the molecular structure of an intermediate generated in the process of generating benzoquinone from a phenyl group at a terminal portion of a siloxane resin included in an insulating paste according to one embodiment.

FIG. 2 illustrates another example of the molecular structure of the intermediate generated in the process of generating benzoquinone from the phenyl group at the terminal portion of the siloxane resin included in the insulating paste according to one embodiment.

FIG. 3 illustrates the molecular structure of benzoquinone.

FIG. 4 illustrates an example of a part of the molecular structure generated by reaction of a π bond of a carbon-carbon double bond of benzoquinone with an oxygen molecule.

FIG. 5 is a flowchart showing an example of a method of producing the insulating paste according to one embodiment.

FIG. 6 is a plan view illustrating the appearance of a solar cell device according to one embodiment as viewed from a first surface side.

FIG. 7 is a plan view illustrating the appearance of the solar cell device according to one embodiment as viewed from a second surface side.

FIG. 8 is a cross-sectional view illustrating a cross section of the solar cell device taken along the line VIII-VIII of FIGS. 6 and 7.

FIGS. 9 to 14 are end views each illustrating the state of the solar cell device according to one embodiment during manufacture.

FIG. 15 illustrates an area of the rear surface of a solar cell device to which a tape has been applied in a peel test targeted at solar cell devices according to the first working example and the third reference example.

### DETAILED DESCRIPTION

Solar cell devices could be improved in the increase in quality of passivation layers. For example, a solar cell device including a layer (also referred to as a protective layer) disposed on a passivation layer to protect the passivation layer is known. The protective layer can be formed on the passivation layer by plasma-enhanced chemical vapor deposition (PECVD).

During formation of the protective layer on the passivation layer by PECVD, however, a plasmatized material gas and the like can lower the quality of the passivation layer. Deterioration of the protective layer over time can also lower its performance of protecting the passivation layer, leading to deterioration in quality of the passivation layer over time.

The inventors of the present application have developed technology to improve the quality of the passivation layer of the solar cell device.

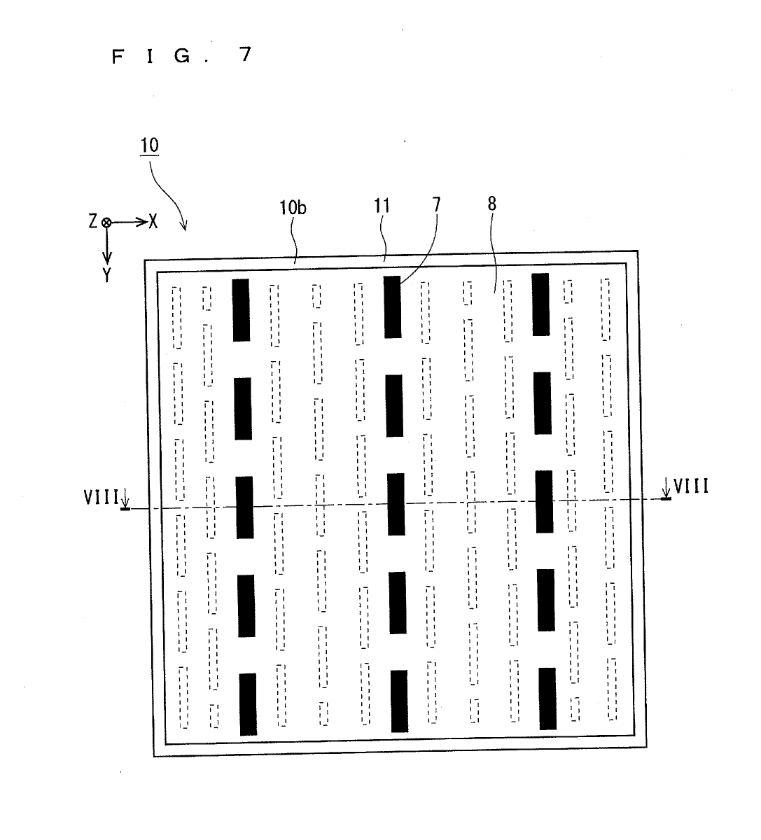

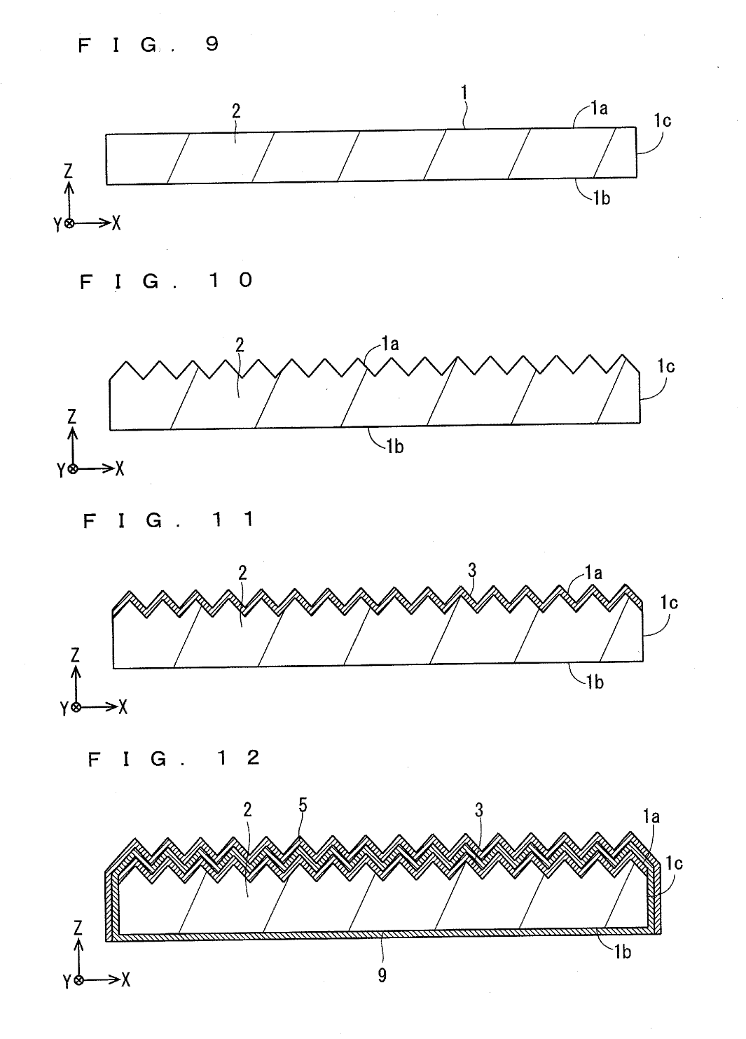

As for this technology, one embodiment will be described below with reference to the drawings. The same reference signs are allocated to components having similar structures and functions in the drawings, and description thereof will not be repeated below. The drawings are schematically shown. FIGS. 6 to 15 are accompanied by right-hand XYZ coordinate systems. In these XYZ coordinate systems, the longitudinal direction of an output extracting electrode 6a on a first surface 10a that is a light-receiving surface of a solar cell device 10 described later is shown as a +Y direction, the transverse direction of the output extracting electrode 6a is shown as a +X direction, and the direction normal to the first surface 10a of the solar cell device 10 described later is shown as a +Z direction. Some electrodes are omitted in FIGS. 8 and 14.

<1. Insulating Paste>

An insulating paste can be used as a material for forming a protective layer that protects a passivation layer of a solar cell device, for example. An insulating paste according to one embodiment includes a siloxane resin and an organic solvent, for example. The siloxane resin herein includes a phenyl group and an alkyl group expressed by the general formula CₙH₂ₙ₊₁, in which n is a natural number. The insulating paste also includes a plurality of fillers, for example. In the siloxane resin included in the insulating paste according to one embodiment, the number of alkyl groups is greater than the number of phenyl groups. The plurality of fillers included in the insulating paste allow for easy control of the viscosity of the insulating paste.

The siloxane resin is a siloxane compound including a Si—O—Si bond (also referred to as a siloxane bond). The siloxane resin is, for example, a low-molecular weight resin (having a molecular weight of 10,000 or less) obtained by hydrolysis and condensation polymerization of alkoxysilane, silazane, or the like. In addition to the siloxane bond, the siloxane resin may include at least one of a Si—R bond, a Si—OR bond, and a Si—OH bond, for example. “R” in the above-mentioned bonds includes an alkyl group, such as a methyl group (—CH₃) and an ethyl group (—C₂H₅), and a phenyl group (—C₆H₅). As the siloxane resin has a molecular weight of 10,000 or less, the siloxane resin can clearly be distinguished from silicone oil, which has a molecular weight of 50,000 or more, for example. The siloxane resin also differs from the silicone oil in that the siloxane resin includes a bond between oxygen and an alkyl group, a bond between oxygen and a phenyl group, and the like, for example.

If the siloxane resin herein includes at least one of the Si—OR bond and the Si—OH bond, the siloxane resin is highly reactive. In this case, the protective layer formed using the insulating paste is expected to be strongly bound to other portions of the solar cell device being in contact with the protective layer. In a case where the siloxane resin includes the Si—OH bond, for example, the siloxane resin is easily bound to silicon, aluminum, and the like as a hydrogen atom is released from the OH group. Alternatively, the siloxane resin is easily bound to silicon, aluminum, and the like as the OH group on the surface of silicon, aluminum, and the like reacts with the Si—OH bond of the siloxane resin to emit a water molecule. In a case where the siloxane resin includes the Si—OR bond, for example, the Si—OR bond is easily hydrolyzed by water, a catalyst, and the like used or generated in the process of producing the insulating paste described later to generate the OH group, if water, the catalyst, and the like remain in the protective layer. The siloxane resin is thus easily bound to silicon, aluminum, and the like as in the case of including the Si—OH bond described above. As described above, an increase in bonding strength of the siloxane resin improves adhesion of the protective layer formed using the insulating paste to the other portions (also referred to as adjacent portions) adjacent to the protective layer. Examples of the other portions adjacent to the protective layer include a substrate (e.g., a silicon substrate) lying under the protective layer, another underlying layer such as an insulating layer, and a metal layer formed on the protective layer.

Adhesion of the protective layer to the adjacent portions improves if there are three or four Si—O bonds for each Si atom included in the siloxane resin. A material including three or four Si—OR bonds for each Si atom is thus used as a precursor of the siloxane resin in producing the insulating paste. This increases at least one of the number of Si—OR bonds and the number of Si—OH bonds in the siloxane resin, which is obtained by hydrolysis and condensation polymerization of the precursor of the siloxane resin, to thereby achieve strong bonding between the protective layer and the adjacent portions. This means that high adhesion of the protective layer to the adjacent portions is achieved. The siloxane resin may include a Si—H bond, a Si—N bond, and the like not having undergone hydrolysis if the siloxane resin is obtained by condensation polymerization of a functional compound including hydrolyzable Si—H bond and Si—N bond.

Adhesion of the protective layer formed using the insulating paste to an electrode formed on the protective layer in a firing process described later can be high if the siloxane resin herein includes not only the alkyl group but also the phenyl group, for example. This makes the electrode less likely to be peeled. As a result, long-term reliability of the solar cell device can improve.

If the number of alkyl groups is herein greater than the number of phenyl groups in the siloxane resin, for example, the electrode formed on the protective layer in the firing process of the method of manufacturing the solar cell device described later includes no or fewer protrusions. Such protrusions can be formed by pyrolysis and the like of the phenyl groups at or near the melting point of aluminum included in the electrode in the firing process, for example. Without any protrusions of the electrode, for example, contact between a light-receiving surface of a first solar cell device and any protrusions of the electrode at the rear-surface side of a second solar cell device is less likely to occur during transportation of a stack of a plurality of solar cell devices. As a result, a break caused due to removal of an electrode for collection (also referred to as a collecting electrode) at a light-receiving surface side of the solar cell device is less likely to occur, leading to reduction of a micro crack and a break of the solar cell device. Collecting efficiency at the light-receiving surface side of the solar cell device is thus less likely to be reduced, and output characteristics of the solar cell device is less likely to be reduced, for example.

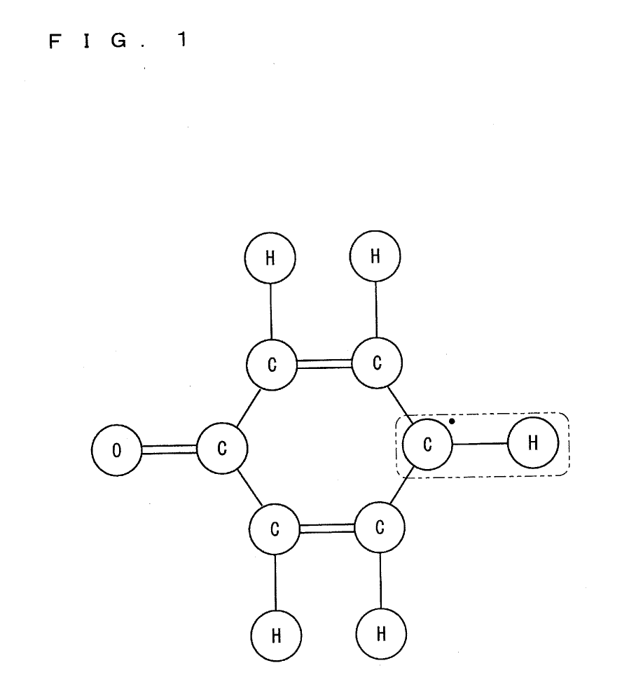

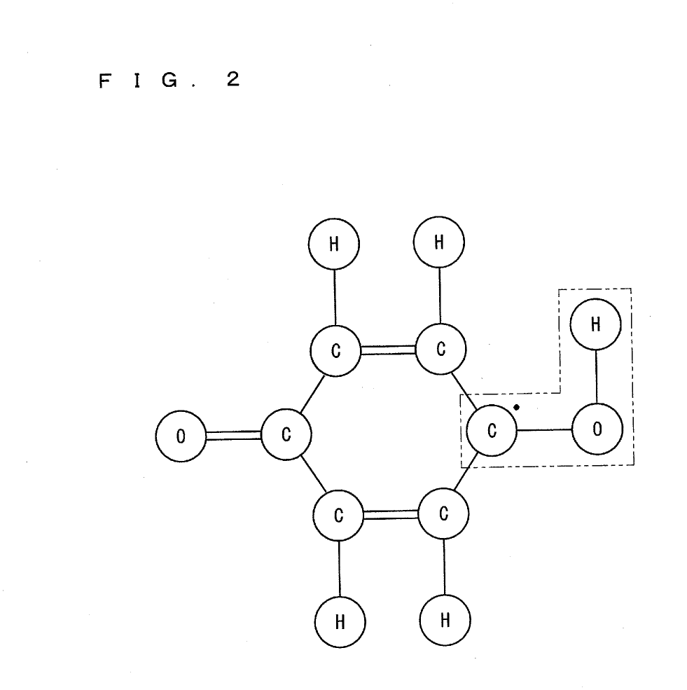

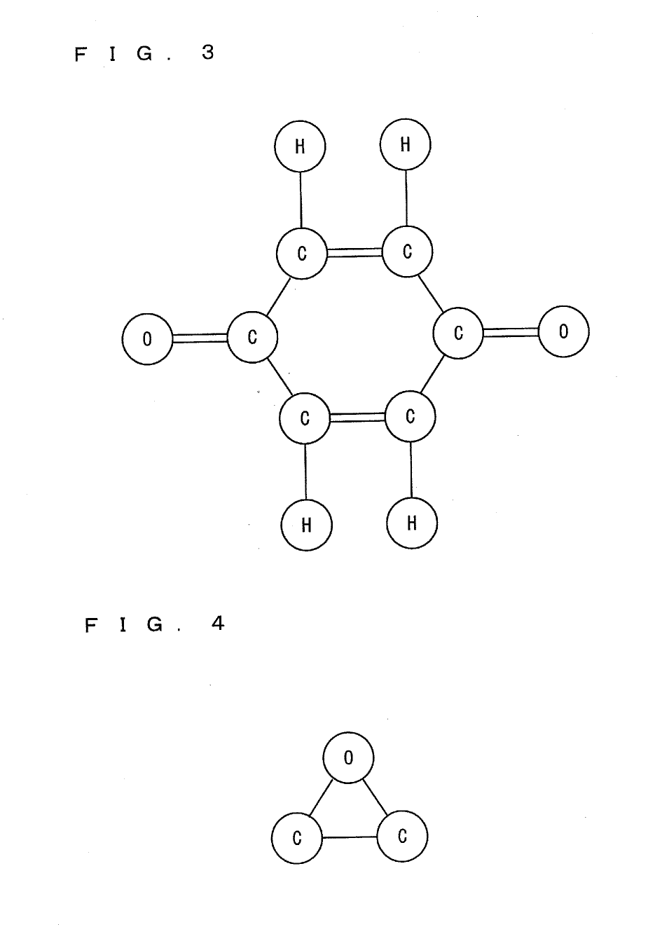

If the siloxane resin herein includes not only the alkyl group but also the phenyl group, for example, the protective layer can include a double bond of elements, such as a carbon-oxygen double bond (C═O) and a carbon-carbon double bond (C═C), in the firing process described later. For example, the protective layer can include p-benzoquinone, which is a yellow solid at normal temperature. Benzoquinone can herein be generated, for example, upon reaction of a part (Si—C₆H₅) of silicon (Si) of the siloxane resin terminated by the phenyl group with water (H₂O) and oxygen (O₂) at high temperature in the firing process of the method of manufacturing the solar cell device described later. In this case, benzoquinone as illustrated in FIG. 3 can be generated from the phenyl group via an intermediate having a molecular structure as illustrated in FIG. 1 or 2, for example. In parts enclosed by alternate long and two short dashes lines in FIGS. 1 and 2, symbols C and black dots above them represent carbon radicals. The protective layer herein includes not only carbon-carbon double bonds (C═C) included in the phenyl group but also a carbon-oxygen double bond (C═O) due to the presence of benzoquinone. The protective layer thus includes more double bonds than the insulating paste. As a result, the following effects obtained by the presence of the double bonds in the protective layer become noticeable.

The above-mentioned double bonds include both a bonds and σ bonds, for example. The π bonds can absorb light in a wavelength range of ultraviolet light to blue light. The a bonds have higher bonding strength than the π bonds, and can absorb ultraviolet light in a shorter wavelength range (a wavelength range of approximately 200 nm or less) than the π bonds. The protective layer including the above-mentioned double bonds can thus absorb more ultraviolet light in a wavelength range of approximately 250 nm to 400 nm included in sunlight than a protective layer including single bonds only including the σ bonds. The protective layer including the above-mentioned double bonds thus reduces exposure of the passivation layer to ultraviolet light, for example. As a result, deterioration of the passivation layer caused by exposure to ultraviolet light can be reduced, for example.

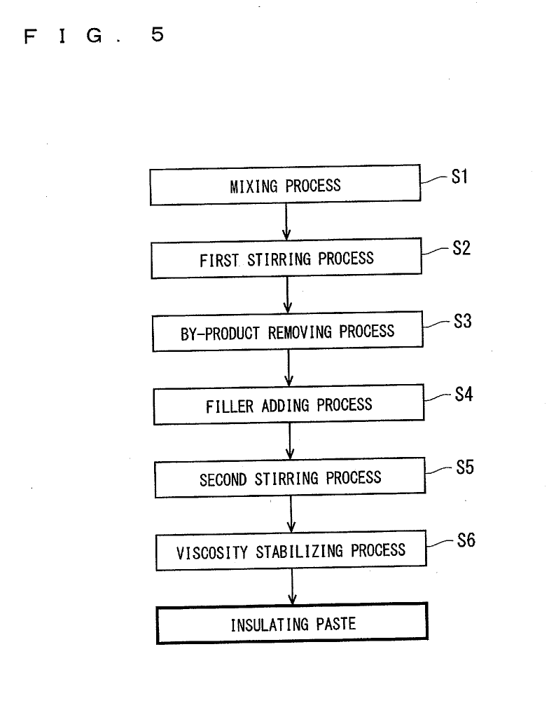

The π bonds included in the above-mentioned double bonds tend to be highly reactive compared with the a bonds. The protective layer including the above-mentioned double bonds is thus more likely to react with acid, moisture, and oxygen. If the protective layer herein includes a carbon-carbon double bond (C═C), for example, the π bond can react to generate an X—C—C—Y bond. X and Y represent hydrogen (H), chlorine (Cl), oxygen (O), and the like. Specifically, if the protective layer includes the carbon-carbon double bond (C═C), the carbon-carbon double bond (C═C) can change into an H—C—C—Cl bond upon reaction of the π bond with hydrochloric acid (HCl), for example. If the protective layer includes the carbon-carbon double bond (C═C), the carbon-carbon double bond (C═C) can change into an H—C—C—OH bond upon reaction of the π bond with water (H₂O), for example. If the protective layer includes the carbon-carbon double bond (C═C), the carbon-carbon double bond (C═C) can change into a 2(-COC—) bond as illustrated in FIG. 4 upon reaction of the a bond with oxygen (O₂), for example. Reaction similar to the reaction occurring in a case where the protective layer includes the carbon-carbon double bond (C═C) can occur in a case where the protective layer includes the carbon-oxygen double bond (C═O), and in a case where the protective layer includes the carbon-nitrogen double bond (C═N), for example. Acid, moisture, and oxygen entering into the solar cell device or generated in a sealing material and the like are thus less likely to reach the passivation layer due to the presence of the protective layer including the above-mentioned double bonds, for example. As a result, deterioration of the passivation layer can be reduced, for example.

If the siloxane resin includes the phenyl group as a substituent, for example, the protective layer formed by application of the insulating paste is more likely to be dried compared with a case where the siloxane resin includes the alkyl group without including the phenyl group as a substituent. The insulating paste can thus be dried in a shorter time or at lower temperature in forming the protective layer.

In a case where the alkyl group includes the methyl group, for example, methanol included in a by-product generated by hydrolysis of the precursor of the siloxane resin is more likely to volatilize. The by-product is thus less likely to remain in the insulating paste. In a case where the insulating paste is printed by screen printing, emulsion used in screen platemaking is less likely to dissolve due to the by-product, and dimensions of a pattern in screen platemaking are less likely to vary. As a result, precision of dimensions of the protective layer can increase.

In a case where the insulating paste (100% by mass) includes 7% by mass to 92% by mass of the siloxane resin, a dense protective layer is formed by applying the insulating paste onto an underlying layer and drying the insulating paste. This can increase the barrier function of the protective layer. The insulating paste is less likely to be gelatinized in a case where the insulating paste (100% by mass) includes 7% by mass to 92% by mass of the siloxane resin. This prevents an excessive increase in viscosity of the insulating paste. If the insulating paste (100% by mass) includes 40% by mass to 90% by mass of the siloxane resin, for example, it is easy to form a dense protective layer and to prevent gelation of the insulating paste.

In a case where the alkyl group further includes a propyl group, for example, the siloxane resin is easily soluble in the organic solvent. This makes the siloxane resin and the fillers less likely to be phase-separated. The viscosity of the insulating paste is thereby stabilized.

As for the relationship between the number of alkyl groups and the number of phenyl groups in the siloxane resin, the siloxane resin includes 5 to 40 phenyl groups relative to 100 alkyl groups, for example. This allows an electrode to include no or fewer protrusions formed by pyrolysis of the phenyl groups and the like as described above in the firing process of the method of manufacturing the solar cell device described later.

The insulating paste may further include a hydrolyzable additive including the Si—O bond or the Si—N bond, and not having undergone condensation polymerization, for example. Such an additive is, for example, expressed by the following general formula 1:

(R1)_{4-a-b}Si(OH)ₐ(OR2)_{b} general formula 1

R1 and R2 in the general formula 1 represent substituents such as alkyl groups including the methyl group (—CH₃), the ethyl group (—CH₂CH₃) and the like and the phenyl groups (—C₆H₅). Furthermore, a and b are expressed by any integers from zero to four, and a+b is expressed by any integer from one to four. For example, a+b may be three or four. R1 and R2 may be the same substituent or may be different substituents.

In a case where the insulating paste herein includes the hydrolyzable additive including the Si—O bond or the Si—N bond, and not having undergone condensation polymerization, for example, the siloxane resin has a higher proportion of the Si—OR bond or the Si—OH bond compared with a case where the insulating paste includes no additive. This is because hydrolysis of the Si—OR bond and condensation polymerization by which the Si—OH bond changes into the siloxane bond and water are less likely to proceed in the siloxane resin, for example. The higher proportion of the Si—OR bond or the Si—OH bond in the siloxane resin leads to higher adhesion of the protective layer to the portions adjacent to the protective layer. The insulating paste shows a tendency to gradually thicken through condensation polymerization and be gelatinized even during storage. The insulating paste according to one embodiment, however, includes the above-mentioned additive, and thus can develop condensation polymerization between the hydrolyzed additive and the siloxane resin having undergone condensation polymerization and having a high molecular weight. This inhibits condensation polymerization between siloxane resins having high molecular weights, so that the insulating paste is less likely to be gelatinized, and does not extremely increase in viscosity.

The siloxane resin included in the insulating paste may partially be the siloxane resin having undergone hydrolysis and condensation polymerization, for example. This reduces variation of the viscosity of the insulating paste caused by hydrolysis of the siloxane resin, for example. The viscosity of the insulating paste is thus easily stabilized. This also reduces a by-product generated by hydrolysis of the siloxane resin included in the insulating paste, for example. In a case where the insulating paste is printed by screen printing, for example, emulsion used in screen platemaking is less likely to dissolve due to the by-product, and dimensions of a pattern in screen platemaking are less likely to vary. As a result, precision of dimensions of the protective layer can increase.

The fillers may each have a surface covered with an organic coating containing a material different from the siloxane resin. This can reduce the number of dangling bonds on the surfaces of the fillers. In this case, the fillers are less likely to repel one another as the surfaces of the fillers are less likely to be electrically charged, for example. In addition, the siloxane resin and the fillers are less likely to bind to each other in this case. The fillers can thus be appropriately aggregated with one another with some distance therebetween. As a result, the fillers are less likely to be evenly dispersed, so that the insulating paste can appropriately thicken. Furthermore, the OH groups are less likely to be formed on the surfaces of the fillers, so that reaction of the OH groups on the surfaces of the fillers with the OH groups of the siloxane resin is reduced, and the fillers and a component of the siloxane resin are less likely to bind to each other. The insulating paste is thus less likely to be gelatinized, and does not extremely increase in viscosity. Spreadability and viscosity stability of the insulating paste can thereby improve, for example. The protective layer formed using such an insulating paste can thus have an improved function of protecting the passivation layer. The insulating paste can stably be applied in a desired pattern even when the insulating paste has been stored for a long time period or is continuously used. As a result, deterioration in quality of the passivation layer of the solar cell device over time can be reduced, leading to improvement in quality of the passivation layer.

If the material contained in the organic coating covering the surfaces of the fillers has a structure in which the number of carbon atoms in a main chain is six or more, or the total number of carbon atoms and silicon atoms in a main chain is six or more, the component of the organic coating improves hydrophobicity of the protective layer. Specific examples of the material for the organic coating covering the surfaces of the fillers include the alkyl group in which the number of carbon atoms in the main chain is six or more and octylsilane in which the total number of carbon atoms and silicon atoms in the main chain is six or more. The polarity is less likely to occur in the alkyl group in which the number of carbon atoms in the main chain is six or more, octylsilane, and the like even upon reaction with the OH group, so that hydrophobicity of the protective layer is easily maintained. The specific examples of the material for the organic coating covering the surfaces of the fillers may also include dimethylpolysiloxane in which the total number of carbon atoms and silicon atoms in the main chain is six or more. Dimethylpolysiloxane includes a spiral main chain and includes the methyl group on the surface thereof to have hydrophobicity, for example. A protective layer having hydrophobicity as described above has stable film quality that is less likely to be changed by moisture and the like, and has maintained insulation. The protective layer formed using such an insulating paste can thus have an improved function of protecting the passivation layer. As a result, deterioration of the passivation layer of the solar cell device over time can be reduced, leading to improvement in quality of the passivation layer. If the total number of carbon atoms and silicon atoms in the main chain in the organic coating covering the surfaces of the fillers is 10,000 or less, for example, a grain diameter of aggregated fillers does not extremely increase, thereby making a thickness of a coating in applying the insulating paste be less likely to vary. This means that spreadability of the insulating paste improves. The protective layer formed using such an insulating paste can thus also have an improved function of protecting the passivation layer.

More specifically, at least one of octylsilane expressed by a chemical formula 1 shown below, a dodecyl group expressed by a chemical formula 2 shown below, and dimethylpolysiloxane expressed by a general formula 2 shown below is used as the material for the organic coating covering the surfaces of the fillers.

C₈H₂₀Si (chemical formula 1)

—C₁₂H₂₅ (chemical formula 2)

—(O—Si(R3)₂)_{c}-Si(R3)₃ (general formula 2)

R3 in the general formula 2 represents the methyl group (CH₃), for example. R3 may partially be the phenyl group (—C₆H₅) or hydrogen (H), for example. In other words, the material for the organic coating may be methylphenylpolysiloxane and methylhydrogenpolysiloxane, for example. Furthermore, c is expressed by an integer equal to or greater than six.

Dimethylpolysiloxane is a polymeric compound including the Si—O—Si bond (siloxane bond). Dimethylpolysiloxane expressed by the general formula 2 is terminated with the methyl group at a first end, and terminated with the surfaces of the fillers at a second end opposite the first end.

The fillers may include a plurality of fillers having surfaces covered with different types of organic coatings, for example. In this case, adhesion of a mask used in platemaking and a substrate, which is presumably caused by reduction of surface tension, can be reduced in applying the insulating paste onto the substrate, for example. This achieves easy application of the insulating paste in a predetermined pattern during printing, thereby improving printability of the insulating paste. In this case, fillers having surfaces covered with the organic coating containing dimethylpolysiloxane expressed by the above-mentioned general formula 2 and fillers having surfaces covered with the organic coating containing octylsilane expressed by the above-mentioned chemical formula 1 can be used, for example.

The gross mass of the fillers is set so that concentration of the fillers in the insulating paste has a value of 3% by mass to 30% by mass, for example. In this case, the viscosity of the insulating paste can be controlled to be suitable for screen printing and the like. The number of fillers in the insulating paste can herein be reduced to some extent to increase the proportion of the siloxane resin. As a result, a dense protective layer can be formed to thereby improve the barrier function of the protective layer. An extremely small number of fillers, however, can cause a crack when the siloxane resins bind to each other as condensation polymerization proceeds in the firing process described later. The barrier function of the protective layer can thus easily be improved by setting the gross mass of the fillers so that the concentration of the fillers in the insulating paste has a value of 5% by mass to 25% by mass, for example.

If the mass of the fillers is smaller than the mass of the siloxane resin in the insulating paste, the viscosity of the insulating paste can be controlled to be suitable for screen printing and the like. In this case, the number of fillers is small to some extent, and the proportion of the siloxane resin is high in the insulating paste. This achieves a dense protective layer, and can thus improve the barrier function. A dense protective layer can easily be formed by including 3 parts by mass to 60 parts by mass of the fillers in 100 parts by mass of the siloxane resin, for example. A dense protective layer can more easily be formed by including 25 parts by mass to 60 parts by mass of the fillers in 100 parts by mass of the siloxane resin, for example.

Examples of the fillers included in the insulating paste according to one embodiment include inorganic fillers including a silicon oxide, an aluminum oxide, and a titanium oxide, for example. For example, the fillers including the silicon oxide improve compatibility, and thus the insulating paste is less likely to be gelatinized. The fillers may be particulate, laminar, flat, hollow, fibrous, or the like. The fillers in such a shape can reduce the decrease in viscosity, which is caused by even dispersion of the fillers. Fillers not in the shape of spheres, such as flat fillers, have larger surface areas, and are thus more likely to be aggregated with one another than fillers in the shape of spheres or a similar shape, for example. As a result, the fillers are less likely to be evenly dispersed.

An average grain diameter of the fillers is set to 1,000 nm or less, for example. The average grain diameter may be an average grain diameter of a primary grain, or may be an average grain diameter of a secondary grain that is aggregated primary grains. This makes a thickness of a coating film in applying the insulating paste be less likely to vary. This means that spreadability of the insulating paste improves. The protective layer formed using such an insulating paste can thus have an improved function of protecting the passivation layer.

The organic solvent is a solvent in which the siloxane resin and the fillers are dispersed. The organic solvent is one of diethyleneglycolmonobutylether, methylcellosolve, ethylcellosolve, ethyl alcohol, 2-(4-methylcyclohexa-3-enyl)propane-2-ol, and 2-propanol, or combinations thereof, for example.

If the insulating paste includes 5% by mass to 90% by mass of the organic solvent, the viscosity of the insulating paste can be controlled to be suitable for screen printing and the like. If the insulating paste includes 5% by mass to 50% by mass of the organic solvent, for example, the viscosity of the insulating paste can easily be controlled to be suitable for screen printing and the like.

If the insulating paste is substantially free of an organic binder, the number of voids generated by decomposition of the organic binder and the like is reduced in the process of drying the insulating paste. This achieves a dense protective layer, and can thus improve the barrier function of the protective layer. However, less than 0.1 parts by mass of the organic binder may be included in 100 parts by mass of the insulating paste.

If the viscosity of the insulating paste is set to 5 Pa·s to 400 Pa·s at a shearing speed of 1 sec⁻¹, bleeding of the insulating paste can be reduced in applying the insulating paste in a desired pattern using screen printing. The insulating paste can easily be applied to have an opening with a width of approximately dozens of micrometers, for example. The viscosity of the insulating paste can be measured using a viscosity-viscoelasticity measuring instrument, for example.

The alkyl groups and the phenyl groups of the siloxane resin are identifiable using infrared spectroscopy (IR), gas chromatograph mass spectrometer (GC-MS), or high performance liquid chromatography (HPLC), for example. The alkyl group content and the phenyl group content of the siloxane resin can be measured using nuclear magnetic resonance (NMR), mass spectrometry (MS), or the like. The number of alkyl groups and phenyl groups in the siloxane resin can thereby be measured.

The molecular weight of the siloxane resin and the organic coating can be measured using gel permeation chromatography (GPC), static light scattering (SLS), intrinsic viscosity (IV), vapor pressure osmometer (VPO), or the like, for example. The composition of the siloxane resin and the organic coating can be measured using the nuclear magnetic resonance (NMR), the infrared spectroscopy (IR), pyrolysis gas chromatography (PGC), or the like, for example. Evolved gas analysis mass spectrometry (EGA-MS) can be used to measure both the molecular weight and the composition of the siloxane resin and the organic coating. The number of carbon atoms and silicon atoms in the main chain in the organic coating can be measured using these measuring methods. In the above-mentioned measuring methods, the siloxane resin and the multiple fillers having surfaces covered with the organic coating may separately be measured. For example, the siloxane resin and the multiple fillers having surfaces covered with the organic coating can be separated by centrifugal separation after dilution of the insulating paste with the organic solvent.

<2. Method of Producing Insulating Paste>

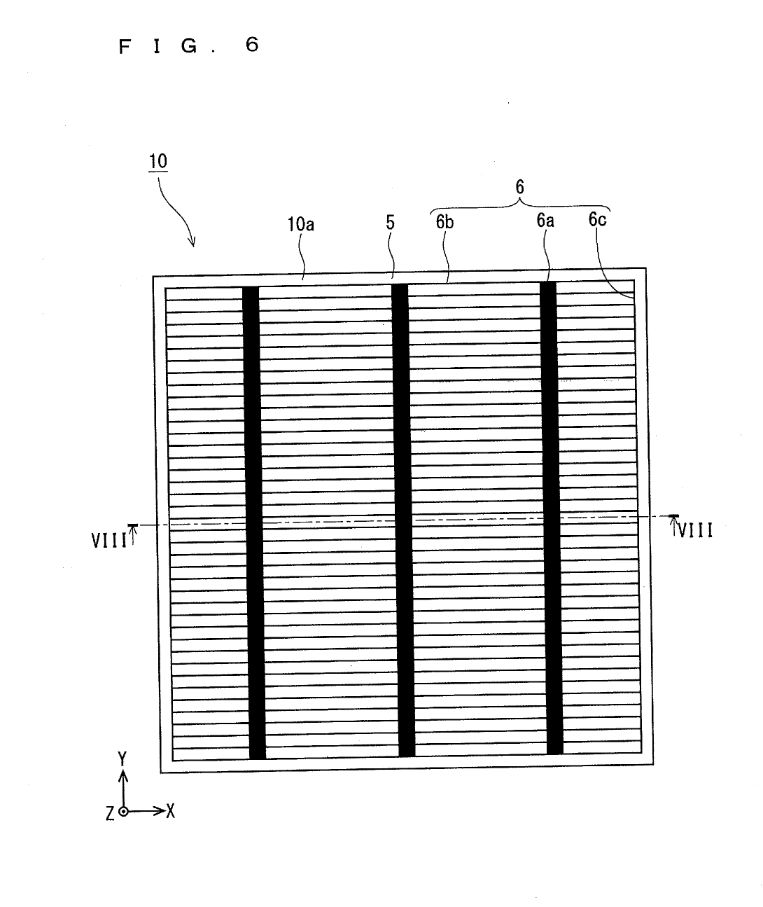

The method of producing the insulating paste according to one embodiment will be described below with reference to FIG. 5.

The insulating paste can be produced by mixing the precursor of the siloxane resin, water for causing hydrolysis of the precursor of the siloxane resin, a catalyst, the organic solvent, and multiple fillers together.

First, a mixing process (step S1) is performed. The precursor of the siloxane resin, water for causing hydrolysis of the precursor of the siloxane resin, the catalyst, and the organic solvent are mixed together in a vessel to produce a mixed solution.

Examples of the precursor of the siloxane resin include a hydrolyzable compound including the Si—O bond or the Si—N bond, for example. The precursor of the siloxane resin undergoes hydrolysis and condensation polymerization to become the siloxane resin.

The hydrolyzable compound including the Si—O bond as the precursor of the siloxane resin includes at least one silicon-containing compound. The silicon-containing compound is, for example, selected from the group consisting of siloxane resins obtained by hydrolysis and condensation polymerization of at least one type of alkoxysilane expressed by the following general formula 3:

(R1)_{4-d}Si(OR2)_{d} general formula 3

In the general formula 3, d is expressed by any integer from one to four.

The precursor of the siloxane resin may partially be mixed in the form of the siloxane resin in which the by-product generated by hydrolysis and condensation polymerization of the phenyl group has been removed after hydrolysis and condensation polymerization, for example. This reduces variation of the viscosity of the insulating paste caused by hydrolysis of the siloxane resin, and thus easily stabilizes the viscosity of the insulating paste, for example. In a case where the insulating paste generated by mixing the siloxane resin in which the by-product has been removed, the organic solvent, and the fillers together is printed by screen printing, for example, emulsion used in screen platemaking is less likely to dissolve due to the by-product. As a result, dimensions of a pattern in screen platemaking are less likely to vary.

In this mixing process, the precursor of the siloxane resin including the alkyl group and the precursor of the siloxane resin including the phenyl group may be mixed together, for example.

Examples of the hydrolyzable compound including the Si—O bond as the precursor of the siloxane resin include a silane compound not including the phenyl group but including the methyl group and a silane compound not including the alkyl group but including the phenyl group. Examples of the silane compound not including the phenyl group but including the methyl group include tetramethoxysilane (Si—(OCH₃)₄) in which d is four, methyltrimethoxysilane (CH₃—Si—(OCH₃)₃) in which d is three, and dimethyldimethoxysilane ((CH₃)₂—Si—(OCH₃)₂) in which d is two. Examples of the silane compound not including the alkyl group but including the phenyl group include tetraphenoxysilane (Si—(OC₆H₅)₄) in which d is four, phenyltriphenoxysilane (C₆H₅—Si—(OC₆H₅)₃) in which d is three, and iphenyldiphenoxysilane ((C₆H₅)₂—Si—(OC₆H₅)₂) in which d is two.

Examples of the hydrolyzable compound including the Si—N bond as the precursor of the siloxane resin include an inorganic compound such as polysilazane expressed by a chemical formula 3 shown below and an organic compound such as hexamethyldisilazane expressed by a chemical formula 4 shown below.

—(H₂SiNH)_{y}— (chemical formula 3)

(CH₃)₃SiNHSi(CH₃)₃ (chemical formula 4)

In the chemical formula 3, y represents an arbitrary natural number.

Water is a liquid used for hydrolysis of the precursor of the siloxane resin. For example, pure water can be used.

The organic solvent is a solvent in which the siloxane resin or the fillers described later is/are dispersed. The organic solvent is one of diethyleneglycolmonobutylether, methylcellosolve, ethylcellosolve, ethyl alcohol, 2-(4-methylcyclohexa-3-enyl)propane-2-ol, and 2-propanol, or combinations thereof, for example.

Inorganic acid or organic acid, such as hydrochloric acid, nitric acid, sulfuric acid, boric acid, phosphoric acid, hydrofluoric acid, and acetic acid, can be used as the catalyst. An inorganic base or an organic base, such as ammonia, sodium hydroxide, potassium hydroxide, barium hydroxide, calcium hydroxide, and pyridine, can also be used as the catalyst. The catalyst may be one of the above-mentioned examples of the inorganic acid, the organic acid, the inorganic base, and the organic base, or combinations thereof.

As for the percentage of the materials mixed together in the mixing process, 10% by mass to 90% by mass of the precursor of the siloxane resin, 5% by mass to 40% by mass (or 10% by mass to 20% by mass) of water, 1 ppm to 1,000 ppm of the catalyst, and 5% by mass to 50% by mass of the organic solvent are mixed together relative to the gross mass of these materials. The siloxane resin obtained by hydrolysis and condensation polymerization of the precursor of the siloxane resin can thereby be included in the insulating paste at an appropriate mass percentage. Furthermore, the insulating paste is less likely to be gelatinized, and the excessive increase in viscosity of the insulating paste can be prevented.

In the mixing process, the precursor of the siloxane resin and water react together to start hydrolysis of the precursor of the siloxane resin. The hydrolyzed precursor of the siloxane resin then undergoes condensation polymerization to start generation of the siloxane resin.

Next, a first stirring process (step S2) is performed. The mixed solution produced in the mixing process is stirred using a mixing rotor, a stirrer, or the like. The precursor of the siloxane resin is further hydrolyzed by stirring the mixed solution. The hydrolyzed precursor of the siloxane resin then undergoes condensation polymerization to continuously generate the siloxane resin. In stirring using the mixing rotor, the mixed solution is stirred at 400 rpm to 600 rpm for 30 minutes to 90 minutes, for example. The precursor of the siloxane resin, water, the catalyst, and the organic solvent can uniformly be mixed together by performing stirring under the above-mentioned conditions.

In the first stirring process, the precursor of the siloxane resin is easily hydrolyzed and condensation polymerized by stirring the mixed solution while heating the mixed solution, for example. This easily stabilizes the viscosity of the mixed solution in and after the first stirring process, for example. As the precursor of the siloxane resin is easily hydrolyzed and condensation polymerized, a stirring time can be reduced to thereby improve the productivity in production of the insulating paste.

Next, a by-product removing process (step S3) is performed. In this process, water, the catalyst, and a by-product of an organic component, such as alcohol, generated by reaction among the organic solvent, the precursor of the siloxane resin, and water are volatilized. By removing the by-product, variation of the viscosity of the insulating paste attributable to volatilization of the organic component described above can be reduced in storing the insulating paste or in continuously applying the insulating paste. In a case where the insulating paste is printed by screen printing, variation of dimensions of a pattern in screen platemaking, which is caused by dissolution of emulsion used in screen platemaking due to the organic component, can be reduced. The hydrolyzed precursor of the siloxane resin undergoes condensation polymerization to continuously generate the siloxane resin also in the by-product removing process. Condensation polymerization of the precursor of the siloxane resin, however, can be reduced by volatilization of water and the catalyst, and thus variation of the viscosity of the mixed solution can be reduced.

In the by-product removing process, the stirred mixed solution is treated using a hot plate, a drying oven, or the like at room temperature to 90° C. (typically, 50° C. to 90° C.) for 10 minutes to 600 minutes, for example. The by-product can be removed when the treatment temperature is within the above-mentioned temperature range. The organic component as the by-product easily volatilizes in the above-mentioned temperature range. The treatment time can thereby be reduced, leading to improvement in productivity in production of the insulating paste.

The organic component as the by-product volatilizes more easily when the by-product removing process is performed under reduced pressure, for example. The treatment time can thereby be reduced, leading to improvement in productivity in production of the insulating paste.

The precursor of the siloxane resin remaining in the first stirring process without being hydrolyzed may be hydrolyzed in the by-product removing process.

Next, a filler adding process (step S4) is performed. Multiple fillers are herein added to the mixed solution having been treated in the above-mentioned by-product removing process (step S3). As the multiple fillers, multiple fillers having surfaces covered with the organic coating can be used, for example. The material for the organic coating has a structure in which the number of carbon atoms in the main chain is six or more, or the total number of carbon atoms and silicon atoms in the main chain is six or more, for example. Inorganic fillers including a silicon oxide can be used as the multiple fillers themselves, for example. The filler adding process (step S4) is herein performed after the first stirring process (step S2) to easily control the viscosity of the mixed solution. The fillers are added so that 3% by mass to 30% by mass of the fillers are included in the insulating paste after production, for example. The fillers may be added so that 5% by mass to 25% by mass of the fillers are included in the insulating paste after production, for example.

Next, a second stirring process (step S5) is performed. Stirring in this process is performed, for example, using a rotation and revolution mixer or the like with respect to the mixed solution to which the fillers have been added. In stirring using the rotation and revolution mixer, the mixed solution is stirred at 800 rpm to 1,000 rpm for each of a rotation part and a revolution part for 1 minute to 10 minutes, for example. The fillers can uniformly be dispersed in the mixed solution by performing stirring under the above-mentioned conditions.

Next, a viscosity stabilizing process (step S6) is performed. The stirred mixed solution is herein kept in storage at room temperature for approximately 2 hours to 24 hours, for example, to stabilize the viscosity of the mixed solution. The viscosity stabilizing process can be omitted if the viscosity of the mixed solution is stabilized in the second stirring process.

The insulating paste can be produced in the above-mentioned processes.

Although the filler adding process (step S4) is performed after the first stirring process (step S2), the fillers may also be added in the mixing process, for example. This eliminates the filler adding process (step S4) and the second stirring process (step S5), leading to improvement in productivity of the insulating paste.

The by-product removing process may not be performed. The insulating paste produced without performing the by-product removing process can be applied by spraying or other methods.

The siloxane resin including the alkyl group may be generated in the mixing process, and the siloxane resin including the phenyl group may be added in the filler adding process, for example.

Alternatively, the insulating paste containing the siloxane resin including the alkyl group and the insulating paste containing the siloxane resin including the phenyl group may be produced, and mixed together to produce the insulating paste containing the siloxane resin including the alkyl group and the phenyl group.

<3. Solar Cell Device>

One example of the solar cell device 10 according to one embodiment is illustrated in FIGS. 6 to 8. One example in which the insulating paste according to one embodiment is applied to a passivated emitter rear cell (PERC) solar cell device will be described below.

As illustrated in FIGS. 6 to 8, the solar cell device 10 has the first surface 10a, which is a light-receiving surface through which light mainly enters, a second surface 10b that is a rear surface located opposite the first surface 10a, and a side surface 10c. The solar cell device 10 includes a silicon substrate 1 as a semiconductor substrate. The silicon substrate 1 has a first surface 1a, a second surface 1b located opposite the first surface 1a, and a side surface 1c. The silicon substrate 1 includes a first semiconductor layer 2 as a semiconductor region of one conductivity type (e.g., a p-type) and a second semiconductor layer 3 located on the first surface 1a side of the first semiconductor layer 2 as a semiconductor region of the opposite conductivity type (e.g., an n-type). The solar cell device 10 further includes a third semiconductor layer 4, an antireflection layer 5, a first electrode 6, a second electrode 7, a third electrode 8, a first passivation layer 9, and a protective layer 11.

The silicon substrate 1 is a substrate made of monocrystalline silicon or polycrystalline silicon, for example. The semiconductor substrate may be made of a material other than silicon as long as the semiconductor substrate includes the first semiconductor layer 2 and the second semiconductor layer 3 as described above.

A case where a p-type semiconductor is used as the first semiconductor layer 2 will be described below. In this case, a p-type silicon substrate is used as the silicon substrate 1, for example. A substrate having a thickness of 250 μm or less or a thin substrate having a thickness of 150 μm or less can be used as the silicon substrate 1, for example. The shape of the silicon substrate 1 is not particularly limited, but gaps between devices can be small in manufacture of a solar cell module including the solar cell device 10 if the silicon substrate 1 has an approximately quadrilateral shape in plan view. In a case where the first semiconductor layer 2 included in the polycrystalline silicon substrate 1 is of the p-type, the silicon substrate 1 includes, as a dopant element, an impurity such as boron and gallium.

The second semiconductor layer 3 is stacked on the first semiconductor layer 2.

The second semiconductor layer 3 has a conductivity type (an n-type in one embodiment) opposite the conductivity type of the first semiconductor layer 2, and is located on the first surface 1a side of the silicon substrate 1. The silicon substrate 1 thereby has a p-n junction between the first semiconductor layer 2 and the second semiconductor layer 3. The second semiconductor layer 3 can be formed by diffusing, as a dopant, impurity elements such as phosphorus on the first surface 1a side of the silicon substrate 1, for example.

As illustrated in FIG. 8, the first surface 1a of the silicon substrate 1 may have a microscopic rough structure (texture) to reduce reflectance of emitted light. The height of each protrusion of the texture is approximately 0.1 μm to 10 μm, for example, and the distance between the apexes of adjacent protrusions is approximately 0.1 μm to 20 μm, for example. Depressions of the texture may each be approximately spherical, and protrusions of the texture may each be pyramidal, for example. The above-mentioned “height of each protrusion” refers to the distance of the apex of the protrusion from a reference line that is defined as an imaginary straight line passing through the bottoms of depressions in a direction perpendicular to the reference line.

The antireflection layer 5 has a function of reducing reflectance of light emitted toward the first surface 10a of the solar cell device 10. The antireflection layer 5 includes a silicon oxide, an aluminum oxide, a silicon nitride layer, or the like, for example. As for a refractive index and the thickness of the antireflection layer 5, a refractive index and a thickness that can achieve low-reflection conditions with respect to sunlight in a wavelength range that is absorbed by the silicon substrate 1 and can contribute to electric power generation are used as appropriate. An antireflection layer having a refractive index of approximately 1.8 to 2.5 and a thickness of approximately 20 nm to 120 nm can be used as the antireflection layer 5, for example.

The third semiconductor layer 4 is located on the second surface 1b side of the silicon substrate 1. The third semiconductor layer 4 has the same conductivity type (a p-type in one embodiment) as the first semiconductor layer 2. The concentration of the dopant included in the third semiconductor layer 4 is higher than the concentration of the dopant included in the first semiconductor layer 2. This means that the third semiconductor layer 4 includes the dopant elements at a higher concentration than the first semiconductor layer 2 doped with the dopant elements to have one conductivity type. The silicon substrate 1 thus includes a semiconductor region having p-type conductivity (also referred to as a p-type semiconductor region) in the second surface 1b as one surface of the silicon substrate 1, for example. The third semiconductor layer 4 forms an internal electric field on the second surface 1b side of the silicon substrate 1. Photoelectric conversion efficiency is thereby less likely to be reduced by recombination of minority carriers at or near the second surface 1b of the silicon substrate 1. The third semiconductor layer 4 can be formed by diffusing dopant elements such as boron and aluminum in a surface portion on the second surface 1b side of the silicon substrate 1, for example. The concentration of the dopant elements included in the first semiconductor layer 2 can herein be set to approximately 5×10¹⁵ stoms/cm³ to 1×10¹⁷ atoms/cm³, and the concentration of the dopant elements included in the third semiconductor layer 4 can herein be set to approximately 1×10¹⁸ stoms/cm³ to 5×10²¹ atoms/cm³. The third semiconductor layer 4 is located at the site of contact between the third electrode 8 described later and the silicon substrate 1, for example.

The first electrode 6 is located on the first surface 1a side of the silicon substrate 1. As illustrated in FIG. 6, the first electrode 6 includes an output extracting electrode 6a and a plurality of linear collecting electrodes 6b. The output extracting electrode 6a is an electrode for externally extracting electricity obtained by electric power generation. The output extracting electrode 6a has a length in its transverse direction (also referred to as a width) of approximately 1.3 mm to 2.5 mm, for example. At least part of the output extracting electrode 6a crosses and is electrically connected to the collecting electrodes 6b. The collecting electrodes 6b are electrodes for collecting electricity obtained by electric power generation performed by the silicon substrate 1. Each of the collecting electrodes 6b has a width of approximately 50 μm to 200 μm, for example. As described above, each of the collecting electrodes 6b has a smaller width than the output extracting electrode 6a. The plurality of collecting electrodes 6b are arranged with a space of approximately 1 mm to 3 mm therebetween, for example. The first electrode 6 has a thickness of approximately 10 μm to 40 μm, for example. The first electrode 6 can be formed by applying a metal paste including silver as a main component in a desired shape by screen printing or the like, and then firing the metal paste, for example. In one embodiment, the main component refers to a component accounting for 50% or more of all the components. An auxiliary electrode 6c having a similar shape to the collecting electrodes 6b may be located along the longitudinal direction of the output extracting electrode 6a in a peripheral portion of the silicon substrate 1 to electrically connect the collecting electrodes 6b to each other, for example.

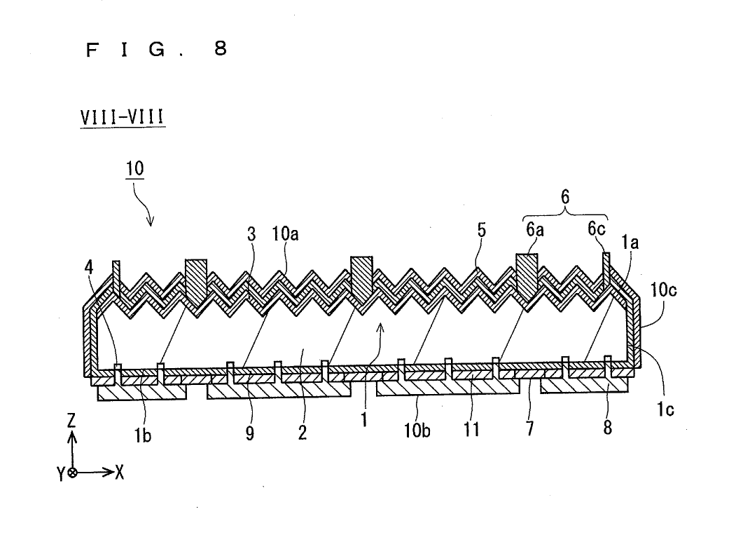

As illustrated in FIGS. 7 and 8, the second electrode 7 and the third electrode 8 are located on the second surface 1b side of the silicon substrate 1. The second electrode 7 is an electrode for externally extracting electricity obtained by electric power generation performed by the solar cell device 10. The second electrode 7 has a thickness of approximately 10 μm to 30 μm, for example. The second electrode 7 has a width of approximately 1.3 mm to 7 mm, for example.

The second electrode 7 includes silver as a main component. The second electrode 7 as described above can be formed by applying a metal paste including silver as a main component in a desired shape by screen printing or the like, and then firing the metal paste, for example.

As illustrated in FIGS. 7 and 8, the third electrode 8 is an electrode for collecting electricity generated by the silicon substrate 1 on the second surface 1b side of the silicon substrate 1. The third electrode 8 is located to be electrically connected to the second electrode 7. At least part of the second electrode 7 is required to be connected to the third electrode 8. The third electrode 8has a thickness of approximately 15 μm to 50 μm, for example.

The third electrode 8 includes aluminum as a main component. The third electrode 8 can be formed by applying a metal paste including aluminum as a main component in a desired shape, and then firing the metal paste, for example. The first passivation layer 9 is located at least on the second surface 1b of the silicon substrate 1. This means that the first passivation layer 9 is located on the p-type semiconductor region of the silicon substrate 1. The first passivation layer 9 has a function of reducing recombination of minority carriers. An example of the material for the first passivation layer 9 includes an aluminum oxide. The aluminum oxide included in the first passivation layer is formed by atomic layer deposition (ALD), for example. The aluminum oxide herein has negative fixed charge, so that minority carriers (electrons in this case) on the second surface 1b side of the silicon substrate 1 are moved away from an interface (the second surface 1b as the surface of the silicon substrate 1) between the first semiconductor layer 2 of the p-type and the first passivation layer 9 by the field effect. This reduces recombination of minority carriers on the second surface 1b side of the silicon substrate 1. The photoelectric conversion efficiency of the solar cell device 10 can thereby be improved. The first passivation layer 9 has a thickness of approximately 10 nm to 200 nm, for example.

The protective layer 11 is located on the first passivation layer 9, which is located on the first semiconductor layer 2, in a desired pattern. The protective layer 11 is in a pattern having a plurality of openings in plan view. The openings may be in the shape of dots or strips (lines), for example. In this case, each opening has a diameter or a width of approximately 10 μm to 500 μm, for example. The distance (also referred to as a pitch of the openings) between the centers of adjacent openings in plan view is approximately 0.3 mm to 3 mm, for example. In applying the metal paste including aluminum as the main component onto the protective layer 11 in the desired shape, the metal paste applied onto the first passivation layer 9 located in the openings in which the protective layer 11 has not been formed fires through the first passivation layer 9 during firing. The metal paste is thus electrically connected to the silicon substrate 1, and aluminum is diffused in the surface portion of the second surface 1b of the silicon substrate 1 to thereby form the third semiconductor layer 4. On the other hand, the metal paste does not fire through the first passivation layer 9 in a region of the first passivation layer 9 covered with the protective layer 11. The passivation effect produced by the first passivation layer 9 is thus less likely to be reduced. The protective layer 11 has a thickness of approximately 0.5 μm to 10 μm, for example. The thickness of the protective layer 11 is appropriately changed according to the type or the content of a component of the insulating paste, the size of a rough structure of the second surface 1b of the silicon substrate 1, the type or the content of a glass frit included in the metal paste, the firing conditions during formation of the third electrode 8, and the like. The protective layer 11 is formed by applying the above-mentioned insulating paste by screen printing, and drying the insulating paste, for example.

The protective layer 11 may be located not only on the first passivation layer 9 formed on the second surface 1b side of the silicon substrate 1 but also on the antireflection layer 5 located on the side surface 1c side and on the first surface 1a side of the silicon substrate 1, for example. In this case, the protective layer 11 can reduce generation of leakage current in the solar cell device 10.

In one embodiment, the protective layer 11 includes a silicon oxide as a main component. Specifically, the protective layer 11 includes the siloxane resin and one or more double bonds selected from the carbon-oxygen double bond, the carbon-carbon double bond, and the carbon-nitrogen double bond, for example. If the protective layer 11 includes benzoquinone, for example, the protective layer 11 includes the siloxane resin, the carbon-oxygen double bond, and the carbon-carbon double bond.

The above-mentioned double bonds are identifiable by measurement by Fourier transform infrared spectroscopy (FT-IR), for example. The solar cell device 10 is used in the state of a solar cell module including a transparent substrate, a back sheet made of a resin, and a sealing member made of an ethylene-vinyl acetate copolymer (EVA) and the like provided between the transparent substrate and the back sheet for sealing. In this case, the back sheet made of a resin is softened in a temperature range from room temperature to approximately 100° C., for example. The back sheet and the sealing member are then cut to peel the back sheet and the sealing member located on the rear surface of the solar cell device 10. The sealing member can be peeled from a light-receiving surface side portion of the solar cell device 10 by inserting fine metal wire and the like between the solar cell device 10 and the sealing member from a peripheral portion of the solar cell device 10, for example. The sealing member may be peeled from the solar cell device 10 by breaking the solar cell device 10 into fragments, for example. The third electrode 8of the solar cell device 10 separated from the sealing member is then removed by grinding or etching using hydrochloric acid and the like to expose the protective layer 11 for measurement by FT-IR. The above-mentioned double bonds are identifiable by referring to a spectrum having a wave number of or around 1630 cm⁻¹ from among spectra having wave numbers obtained by measurement by FT-IR, for example. Elements included in the double bonds are identifiable by gas chromatography mass spectrometry (GC-MS), time-of-flight secondary ion mass spectrometry (TOF-SIMS), or the like, for example. In a case where the protective layer is soluble, elements included in the double bonds are identifiable by nuclear magnetic resonance (NMR), for example.

The protective layer 11 easily absorbs ultraviolet light if the protective layer 11 includes one or more double bonds selected from the carbon-oxygen double bond, the carbon-carbon double bond, and the carbon-nitrogen double bond, for example. This reduces exposure of the first passivation layer 9 to ultraviolet light, for example. As a result, deterioration of the first passivation layer 9 caused by exposure to ultraviolet light can be reduced, for example. In the protective layer 11, one or more double bonds selected from the carbon-oxygen double bond, the carbon-carbon double bond, and the carbon-nitrogen double bond easily react with acid, moisture, oxygen, and the like due to the presence of the π bond, which is highly reactive, for example. The protective layer 11 including the above-mentioned double bonds can thus capture acid, moisture, oxygen, and the like entering into or generated in the solar cell device 10. Acid, moisture, and the like entering into or generated in the solar cell device 10 are less likely to reach the first passivation layer 9 due to the presence of the protective layer 11 including the above-mentioned double bonds, for example. As a result, the first passivation layer 9 is less likely to be deteriorated, for example.

The protective layer 11 may include a component derived from a component of the organic coating covering the multiple fillers included in the insulating paste, for example. For example, the protective layer 11 may include an organic component that is different from the siloxane resin, and has a structure in which the number of carbon atoms in the main chain is six or more, or the total number of carbon atoms and silicon atoms in the main chain is six or more. Such an organic component can include an alkyl group in which the number of carbon atoms in the main chain is six or more, octylsilane, and the like, for example. In this case, the polarity is less likely to occur in the alkyl group in which the number of carbon atoms in the main chain is six or more and octylsilane even upon reaction with the OH group, for example, so that hydrophobicity of the protective layer 11 can be maintained. The protective layer 11 thus has stable film quality that is less likely to be changed by moisture and the like, and has high durability, for example. The protective layer 11 can thus have an improved function of protecting the first passivation layer 9. As a result, the quality of the first passivation layer 9 of the solar cell device is maintained, leading to improvement in quality of the first passivation layer 9.

The protective layer 11 may include dimethylpolysiloxane including a —(O—Si—(CH₃)₂)-bond and a —(Si—(CH₃)₃) bond, for example. Dimethylpolysiloxane included in the protective layer 11 is identifiable by analysis such as FT-IR, EGA-MS, and TOF-SIMS, for example. The protective layer 11 can include dimethylpolysiloxane if the organic coating covering the surfaces of the multiple fillers included in the insulating paste includes dimethylpolysiloxane, for example. Dimethylpolysiloxane is identifiable by referring to a spectrum having a wave number of or around 1250 cm⁻¹ to 1300 cm⁻¹ from among spectra having wave numbers obtained by measurement by FT-IR, for example.

Adhesion of the protective layer 11 to the other portions (adjacent portions) adjacent to the protective layer 11 can improve if at least one of the Si—OH bond and the Si—OR bond included in the insulating paste remains in the protective layer 11, for example. The adjacent portions include the third electrode 8 and the first passivation layer 9, for example. For example, OH exists on the surfaces of aluminum (Al) and silicon (Si). If the Si—OR bond exists on the surface of the protective layer 11, R and OH react with each other to emit alcohol, thereby forming the siloxane bond (Si—O—Si bond), a Si—O—Al bond, and the like. If the Si—OH bond exists on the surface of the protective layer 11, H and OH react with each other to emit water, thereby forming the siloxane bond (Si—O—Si bond), the Si—O—Al bond, and the like. Adhesion of the protective layer 11 to the other portions (adjacent portions) adjacent to the protective layer 11 can thus improve. The Si—OH bond included in the protective layer 11 is identifiable by measurement by FT-IR, for example. The Si—OR bond included in the protective layer 11 is identifiable by measurement by NMR, for example.

The protective layer 11 may be formed not only on the first passivation layer 9 formed on the second surface 1b side of the silicon substrate 1 but also on the antireflection layer 5 formed on the side surface 1c and a peripheral portion of the first surface 1a of the silicon substrate 1, for example. In this case, the protective layer 11 can reduce the leakage current in the solar cell device 10.

A second passivation layer including a silicon oxide may be formed between the p-type semiconductor region (the first semiconductor layer 2 in one embodiment) and the first passivation layer 9 including the aluminum oxide layer, for example. This can improve passivation performance. A second passivation layer having a thickness of approximately 0.1 nm to 1 nm is less likely to reduce the field passivation effect produced by the first passivation layer 9, even if the second passivation layer, which includes the silicon oxide, has positive fixed charge.

The third electrode 8 may be formed on the second surface 1b of the solar cell device 10 in the shape of the collecting electrodes 6b to be connected to the second electrode 7, for example. Such a structure can cause light that is reflected from the ground and the like, and entering into the solar cell module through the rear surface thereof to contribute to electric power generation, to thereby improve output of the solar cell module, for example.

A silicon oxide layer formed by ALD may further be located between the first passivation layer 9 including the aluminum oxide layer and the protective layer 11, for example. As the silicon oxide layer is formed by ALD, the silicon oxide layer is denser than the protective layer 11. The silicon oxide layer denser than the protective layer 11 can be observed using a transmission electron microscope (TEM). The silicon oxide layer formed between the first passivation layer 9 and the protective layer 11 functions as a buffer layer between the first passivation layer 9 and the protective layer 11. Adhesion of the first passivation layer 9 to the protective layer 11 can thus further improve. The silicon oxide layer has a thickness of approximately 5 nm to 15 nm, for example. A silicon oxide layer having a thickness in the above-mentioned range is less likely to reduce the field passivation effect produced by negative fixed charge of the first passivation layer 9, even if the silicon oxide layer has positive fixed charge. The silicon oxide layer, however, should have a thickness smaller than the first passivation layer 9.

<4. Method of Manufacturing Solar Cell Device>

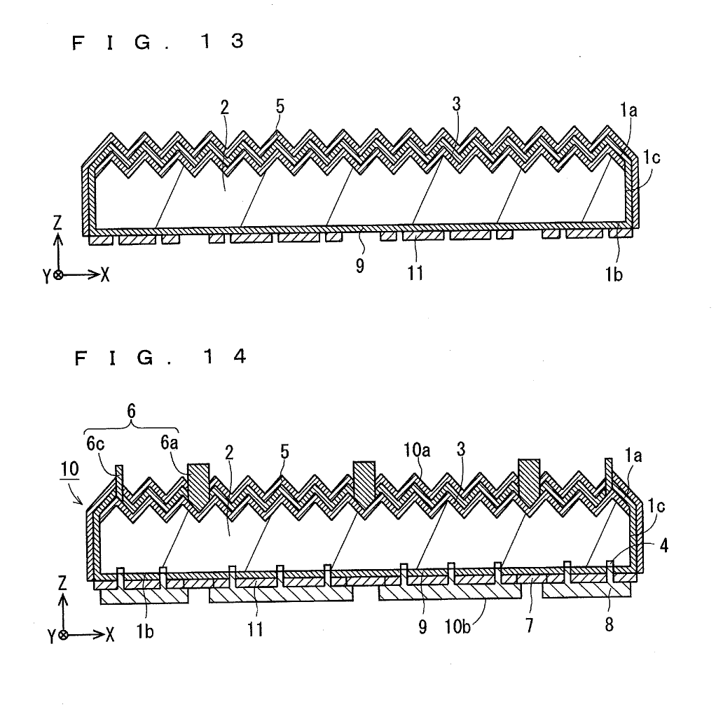

Each process of the method of manufacturing the solar cell device 10 will be described in detail with reference to FIGS. 9 to 14.

First, the silicon substrate 1 is prepared as illustrated in FIG. 9. The silicon substrate 1 is formed by an existing method such as Czochralski (CZ) or casting, for example. An example in which a p-type polycrystalline silicon substrate is used as the silicon substrate 1 will be described below.

An ingot of polycrystalline silicon is herein produced by casting, for example. Next, the ingot is cut into slices each having a thickness of 250 μm or less, for example, to produce the silicon substrate 1. In order to remove a mechanically-damaged layer and a contaminated layer of the cut surface of the silicon substrate 1, the surface of the silicon substrate 1 may be slightly etched with an aqueous solution of NaOH, KOH, hydrofluoric acid, nitrohydrofluoric acid, or the like.

Next, the texture is formed on the first surface 1a of the silicon substrate 1 as illustrated in FIG. 10. The texture can be formed by wet etching using alkaline solution of NaOH and the like or acid solution of nitrohydrofluoric acid and the like, or dry etching such as reactive ion etching (RIE), for example.

Next, the process of forming the second semiconductor layer 3 as an n-type semiconductor region is performed with respect to the first surface 1a of the silicon substrate 1 having the texture formed in the above-mentioned process, as illustrated in FIG. 11. Specifically, the second semiconductor layer 3 of the n-type is formed in a surface portion on the first surface 1a side of the silicon substrate 1 having the texture.

The second semiconductor layer 3 can be formed by application thermal diffusion in which a P₂O₅ (diphosphorus pentaoxide) paste is applied onto the surface of the silicon substrate 1, and phosphorus is then thermally diffused, or by gas phase thermal diffusion using a POCl₃ (phosphorus oxychloride) gas as the source of diffusion, for example. The second semiconductor layer 3 is formed to have a depth of approximately 0.1 μm to 2 μm and a sheet resistance of approximately 40Ω/□ to 200Ω/□. In the gas phase thermal diffusion, the silicon substrate 1 is heat treated in an atmosphere of a diffused gas including POCl₃ and the like in a temperature range of approximately 600° C. to 800° C. for approximately 5 minutes to 30 minutes to form phosphorus glass on the surface of the silicon substrate 1, for example. The silicon substrate 1 is then heat treated in an atmosphere of an inert gas such as argon or nitrogen at a high temperature of approximately 800° C. to 900° C. for approximately 10 minutes to 40 minutes. Phosphorus is thereby diffused from the phosphorus glass into the surface portion of the silicon substrate 1 to form the second semiconductor layer 3 on the first surface 1a side of the silicon substrate 1.

Next, if the second semiconductor layer is also formed on the second surface 1b side in the above-mentioned process of forming the second semiconductor layer 3, the second semiconductor layer formed on the second surface 1b side is removed by etching, for example. A p-type conductivity region is thereby exposed on the second surface 1b side. The second semiconductor layer formed on the second surface 1b side can be removed by immersing a portion of the silicon substrate 1 on the second surface 1b side in a nitrohydrofluoric acid solution, for example. The phosphorus glass adhering to the first surface 1a of the silicon substrate 1 is then removed by etching.

Removal of and damage to the second semiconductor layer 3 formed on the first surface 1a side can be reduced by removing the second semiconductor layer formed on the second surface 1b side by etching while allowing the phosphorus glass to remain on the first surface 1a side as described above. In this case, the second semiconductor layer formed at the side surface 1c of the silicon substrate 1 may also be removed.

In the above-mentioned process of forming the second semiconductor layer 3, a diffusion mask may be formed in advance on the second surface 1b side, and removed after formation of the second semiconductor layer 3 by gas phase thermal diffusion and the like. A structure similar to the above-mentioned structure can be formed in this process. In this case, the process of removing the second semiconductor layer on the second surface 1b side is unnecessary because the second semiconductor layer is not formed on the second surface 1b side.

The polycrystalline silicon substrate 1 including the second semiconductor layer 3 as the n-type semiconductor layer formed on the first surface 1a side, and the first semiconductor layer 2 having the texture on its surface can be prepared in the above-mentioned manner.

Next, the first passivation layer 9 is formed on the first surface 1a of the second semiconductor layer 3 and the second surface 1b of the first semiconductor layer 2 as illustrated in FIG. 12. The first passivation layer 9 mainly includes an aluminum oxide, for example. The antireflection layer 5 is formed on the first passivation layer 9. The antireflection layer 5 mainly includes a silicon nitride film, for example.

The first passivation layer 9 can be formed by ALD, for example. The first passivation layer 9 can be formed by ALD on the entire surface of the silicon substrate 1 including the side surface 1c of the silicon substrate 1. In forming the first passivation layer 9 by ALD, the silicon substrate 1 in which the above-mentioned second semiconductor layer 3 has been formed is first placed in a chamber of a layer formation apparatus, for example. The following processes A to D are repeated a plurality of times while heating the silicon substrate 1 to a temperature range of 100° C. to 250° C. to form the first passivation layer 9 including the aluminum oxide. The first passivation layer 9 having a desired thickness is thereby formed.

In a case where the second passivation layer including the silicon oxide is formed between the first semiconductor layer 2 and the first passivation layer 9 including the aluminum oxide, the second passivation layer can be formed by ALD. In this case, the second passivation layer including the silicon oxide can be formed by repeating the following processes A to D a plurality of times while heating the silicon substrate 1 to a temperature range similar to the above-mentioned temperature range. Details of the processes A to D are as follows:

[Process A] A silicon material, such as bisdiethylaminosilane (BDEAS), for formation of a silicon oxide layer or an aluminum material, such as trimethylaluminum (TMA), for formation of an aluminum oxide is supplied onto the silicon substrate 1 along with a carrier gas, such as an Ar gas or a nitrogen gas. The silicon material or the aluminum material is thereby adsorbed onto the entire surface of the silicon substrate 1. BDEAS or TMA is supplied for approximately 15 msec to 3,000 msec, for example. The surface of the silicon substrate 1 may be terminated with the OH group at the start of the process A. This means that the surface of the silicon substrate 1 may have a Si—O—H structure. This structure can be formed by cleaning the silicon substrate 1 with pure water after treatment with diluted hydrofluoric acid, for example.

[Process B] The chamber of the layer formation apparatus is purified with a nitrogen gas to remove the silicon material or the aluminum material in the chamber. From among the silicon material or the aluminum material physically and chemically adsorbed onto the silicon substrate 1, a silicon material or an aluminum material other than a component chemically adsorbed at an atomic layer level is further removed. The chamber is purified with the nitrogen gas for approximately one second to dozens of seconds, for example.

[Process C] An oxidizer such as water and an ozone gas is supplied into the chamber of the layer formation apparatus to remove the alkyl group included in BDEAS or TMA so that the alkyl group is substituted with the OH group. An atomic layer of a silicon oxide or an aluminum oxide is thereby formed on the silicon substrate 1. The oxidizer is supplied into the chamber for approximately 750 msec to 1,100 msec, for example. The silicon oxide or the aluminum oxide is more likely to include a hydrogen atom by supplying hydrogen (H) along with the oxidizer into the chamber, for example.

[Process D] The chamber of the layer formation apparatus is purified with a nitrogen gas to remove the oxidizer in the chamber. In this case, an oxidizer and the like not having contributed to reaction during formation of the silicon oxide or the aluminum oxide at the atomic layer level on the silicon substrate 1 are removed, for example. The chamber is purified with the nitrogen gas for approximately one second to dozens of seconds, for example.

A series of processes from the processes A to D is thereafter repeated a plurality of times to form the silicon oxide layer or the aluminum oxide layer having a desired thickness.

The antireflection layer 5 can be formed by PECVD or sputtering, for example. In a case where PECVD is used, the silicon substrate 1 is preheated at a temperature higher than a temperature at which the antireflection layer 5 is formed, for example. Then, a mixed gas of silane (SiH₄) and ammonia (NH₃) is diluted with nitrogen (N₂), and the diluted gas is plasmatized by glow discharge decomposition at a reaction pressure of 50 Pa to 200 Pa, and deposited on the heated silicon substrate 1 to form the antireflection layer 5. In this case, the layer is formed at a temperature of approximately 350° C. to 650° C., and the preheating temperature is set to be higher than the layer forming temperature by approximately 50° C. A frequency of a high-frequency power supply required for glow discharge is set to 10 kHz to 500 kHz. A flow rate of the gas is appropriately determined in accordance with the size of the reaction chamber and the like. The flow rate of the gas is in a range of 150 ml/min (sccm) to 6,000 ml/min (sccm), and a ratio (B/A) of the flow rate B of ammonia to the flow rate A of silane is 0.5 to 15, for example.

Next, the protective layer 11 is formed on at least part of the first passivation layer 9 as illustrated in FIG. 13. First, the insulating paste according to one embodiment is herein applied onto the first passivation layer 9, for example. The insulating paste is then fired to form the protective layer 11 on the first passivation layer 9.

Specifically, the insulating paste according to one embodiment is applied onto at least part of the first passivation layer 9 in a desired pattern by screen printing and the like, for example. The insulating paste is then dried at a maximum temperature of 150° C. to 350° C. for 1 minute to 10 minutes using a hot plate, a drying oven, or the like. The protective layer 11 in the desired pattern can thereby be formed on the first passivation layer 9. If the protective layer 11 is formed under the above-mentioned conditions, a portion of the first passivation layer 9 covered with the protective layer 11 is not fired through by the metal paste during formation of the third electrode 8 described later, for example. The passivation effect produced by the first passivation layer 9 is thus less likely to be reduced. In addition, adhesion of the protective layer 11 to the first passivation layer 9 and the third electrode 8is less likely to be reduced, for example. A formation of the protective layer 11 under the above-mentioned conditions is less likely to adversely affect the quality of the first passivation layer 9 on the second surface 1b side than a formation of the protective layer 11 by PECVD. This means that the quality of the first passivation layer 9 can improve.

If the number of alkyl groups is herein greater than the number of phenyl groups in the siloxane resin included in the insulating paste used to form the protective layer 11, for example, the third electrode 8formed on the protective layer 11 in the firing process described later includes no or fewer protrusions. The third electrode 8 is also less likely to be peeled from the protective layer 11, for example. The phenyl group included in the insulating paste delays condensation polymerization of the insulating paste and contraction of the insulating paste in the firing process described later, for example. This reduces stress applied between the protective layer 11 and the third electrode 8, and can improve adhesion of the protective layer 11 to the third electrode 8. As for the relationship between the number of alkyl groups and the number of phenyl groups in the siloxane resin included in the insulating paste, the siloxane resin can have 5 to 40 phenyl groups relative to 100 alkyl groups, for example.

The protective layer 11 is formed at a position other than a position at which the third electrode 8 is in contact with the second surface 1b of the silicon substrate 1, for example. The protective layer 11 formed in the desired pattern to have a plurality of openings on the first passivation layer 9 eliminates the need for the process of removing the protective layer 11 through emission of a laser beam and the like. This can improve the productivity in the manufacture of the solar cell device 10.

The amount of the applied insulating paste is appropriately changed according to the size of the rough structure of the second surface 1b of the silicon substrate 1, the type or the content of the glass frit included in the metal paste including aluminum as a main component described later, the firing conditions during formation of the third electrode 8, and the like.

Next, as illustrated in FIG. 14, the first electrode 6, the second electrode 7, and the third electrode 8 are formed as described below.

The first electrode 6 can be produced using a metal paste (also referred to as a first metal paste) including a metal powder including silver as a main component, an organic vehicle, and a glass frit, for example. First, the first metal paste is herein applied onto a portion on the first surface 1a side of the silicon substrate 1 by screen printing or the like. The first metal paste may be dried by vaporizing a solvent at a predetermined temperature after application onto the portion on the first surface 1a side. The first metal paste is then fired in a firing oven at a maximum temperature of 600° C. to 850° C. for approximately dozens of seconds to dozens of minutes to form the first electrode 6. The output extracting electrode 6a and the collecting electrodes 6b can be formed in the same process by using screen printing.

The second electrode 7 can be produced using a metal paste (also referred to as a second metal paste) including a metal powder including silver as a main component, an organic vehicle, and a glass frit, for example. First, the second metal paste is herein applied onto a portion on the second surface 1b side of the silicon substrate 1 by screen printing or the like. The second metal paste may be dried after application by vaporizing a solvent at a predetermined temperature. The second metal paste is then fired in a firing oven at a maximum temperature of 600° C. to 850° C. for approximately dozens of seconds to dozens of minutes to form the second electrode 7 on the second surface 1b side of the silicon substrate 1.

The third electrode 8can be produced using a metal paste (also referred to as a third metal paste) including a metal powder including aluminum as a main component, an organic vehicle, and a glass fit, for example. First, the third metal paste is herein applied onto a portion on the second surface 1b side of the silicon substrate 1 to be in contact with a part of the second metal paste applied in advance. In this case, the third metal paste may be applied onto almost the entire surface of a portion on the second surface 1b side of the silicon substrate 1 except for a part of the portion at which the second electrode 7 is formed. The third metal paste can be applied by screen printing or the like. The third metal paste may be dried after application by vaporizing a solvent at a predetermined temperature. The third metal paste is then fired in a firing oven at a maximum temperature of 600° C. to 850° C. for approximately dozens of seconds to dozens of minutes to form the third electrode 8on the second surface 1b side of the silicon substrate 1. In firing, the third metal paste fires through the first passivation layer 9 to be connected to the first semiconductor layer 2, so that the third electrode 8 is formed. The third semiconductor layer 4 is formed together with the third electrode 8. In contrast, a part of the third metal paste located on the protective layer 11 is blocked by the protective layer 11. The first passivation layer 9 is thus hardly adversely affected during firing of the third metal paste.

The solar cell device 10 can be manufactured in the above-mentioned processes. The second electrode 7 may be formed after formation of the third electrode 8, for example. The second electrode 7 may not be in direct contact with the silicon substrate 1, for example. The second electrode 7 may be located on the protective layer 11, for example.

The first electrode 6, the second electrode 7, and the third electrode 8 may be formed, after application of respective metal pastes, by firing these metal pastes at the same time. This can improve the productivity of the solar cell device 10, and improve the output characteristics of the solar cell device 10 as heat history with respect to the silicon substrate 1 is reduced.

In the firing process performed to form the first electrode 6, the second electrode 7, and the third electrode 8, heat treatment is performed at a maximum temperature of 600° C. to 850° C. The melting point of aluminum, which is included in the third metal paste as a main component, is herein approximately 660° C., for example. A temperature range in which the bond between silicon and the methyl group is pyrolyzed is approximately 400° C. or more. A temperature range in which the bond between silicon and the propyl group is pyrolyzed is approximately 500° C. or more. A temperature range in which the bond between silicon and the phenyl group is pyrolyzed is approximately 600° C. or more. In firing the third metal paste, in a temperature range of approximately 400° C. to 500° C., for example, methane or methanol produced through pyrolysis of the bond between silicon and the methyl group and the like passes through, in gaseous form, the third metal paste via gaps between aluminum powders having not been molten. In this case, if a portion (Si—CH₃) of the siloxane resin in which silicon is terminated with the methyl group reacts with water (H₂O), for example, a portion (Si—OH) in which silicon is terminated with a hydroxy group (OH) and methane (CH₄) can be produced. If a portion (Si—CH₃) of the siloxane resin in which silicon is terminated with the methyl group reacts with water (H₂O) and oxygen (O₂), for example, a portion (Si—OH) in which silicon is terminated with the hydroxy group (OH) and methanol (CH₃OH) can be produced. Methane and methanol can be detected by degassing analysis performed through heating from room temperature to 800° C. In a temperature range of approximately 500° C. to 600° C., for example, propane produced by pyrolysis of the bond between silicon and the propyl group and the like passes through, in gaseous form, the third metal paste via gaps between aluminum powders having not been molten. In this case, if a portion (Si—C₃H₇) of the siloxane resin in which silicon is terminated with the propyl group reacts with water (H₂O), for example, a portion (Si—OH) in which silicon is terminated with the hydroxy group (OH) and propane (C₃H₈) can be produced. Propane can be detected by degassing analysis performed through heating from room temperature to 800° C.

On the other hand, in a state in which aluminum is molten or semi-molten in a temperature range of approximately 600° C. to 850° C., a substance produced by pyrolysis of the bond between silicon and the phenyl group and the like passes through, in gaseous form, the third metal paste to the outside while lifting the molten or semi-molten aluminum. Examples of the above-mentioned substance produced by pyrolysis and the like include p-benzoquinone, methyl-p-benzoquinone, tetramethyl-p-benzoquinone, tetrachloro-p-benzoquinone, benzene and the like. The lifted aluminum portions of the third metal paste can thus remain as protruding portions (protrusions) when the third metal paste is solidified during cooling of the firing process. The resulting protrusions each have a height of approximately 10 μm to 50 μm, for example. The sizes of the protrusions are identifiable by observing the cross section of the third electrode 8 using a scanning electron microscope (SEM) or an optical microscope, for example.

If the number of alkyl groups is herein greater than the number of phenyl groups in the siloxane resin included in the insulating paste used to form the protective layer 11, for example, the third electrode 8formed on the protective layer 11 in the firing process includes no or fewer protrusions. If the third electrode 8includes no or fewer protrusions, for example, contact between the first surface 10a as the light-receiving surface of a first solar cell device 10 and any protrusions of the third electrode 8 of a second solar cell device 10 is less likely to occur during transportation of a stack of a plurality of solar cell devices 10. As a result, a break caused due to removal of the collecting electrodes 6b on the first surface 10a side of the solar cell device 10 is less likely to occur, leading to reduction of a micro crack and a break of the solar cell device 10. Collecting efficiency on the first surface 10a side of the solar cell device 10 is thus less likely to be reduced, and output characteristics of the solar cell device 10 is less likely to be reduced, for example.

The phenyl group may remain in the protective layer 11, for example. The remaining phenyl group is identifiable by IR. The phenyl group remaining in the protective layer 11 can reduce moisture permeability of the protective layer 11. As a result, moisture is less likely to reach the first passivation layer 9, and deterioration of the first passivation layer 9 can be reduced.

<5. Working Examples>

Working examples of one embodiment will be described next.

<5-1. Production of Insulating Pastes According to First Working Example and First to Third Reference Examples>

The first working example of the insulating paste will be described herein.

The insulating paste according to the first working example was produced as follows:

First, in the mixing process, methyltrimethoxysilane as the precursor of the siloxane resin, water, diethyleneglycolmonobutylether as the organic solvent, and hydrochloric acid as the catalyst were mixed together in a vessel to thereby produce a mixed solution. In this case, the mixed solution was produced to include 45% by mass of methyltrimethoxysilane, 25% by mass of water, 30% by mass of diethyleneglycolmonobutylether, and 50 ppm of hydrochloric acid.

Next, in the first stirring process, the mixed solution was stirred using a mixing rotor at 550 rpm for 45 minutes.

Next, in the by-product removing process, methyl alcohol being an organic component as the by-product generated by hydrolysis of methyltrimethoxysilane, water, and the catalyst were volatilized using a drying oven at 85° C. for 180 minutes.

Next, in the filler adding process, fillers including a silicon oxide and having surfaces covered with a dimethylpolysiloxane coating were added to the mixed solution.

In this case, the gross mass of the fillers in the mixed solution was set to 15% by mass. The number of silicon atoms in the main chain of dimethylpolysiloxane was herein approximately 1,500. The number of silicon atoms was measured by NMR and IV.

In the filler adding process, phenyltriphenoxysilane having undergone hydrolysis, condensation polymerization, and removal of the by-product was also added to the mixed solution. In this case, the gross mass of the siloxane resin including the phenyl group in the insulating paste was set to 10% by mass.

Next, in the second stirring process, the mixed solution was stirred using a rotation and revolution mixer at 850 rpm for 8 minutes.

Next, in the viscosity stabilizing process, the mixed solution was kept in storage at room temperature for a predetermined time period. The insulating paste according to the first working example was kept in storage at room temperature for one hour.

The insulating paste according to the first working example was produced to include 55% by mass of the siloxane resin, 30% by mass of diethyleneglycolmonobutylether, and 15% by mass of the fillers in the above-mentioned processes. As described above, the precursor of the siloxane resin including the methyl group and the precursor of the siloxane resin including the phenyl group were mixed together to include 45% by mass of the precursor of the siloxane resin including the methyl group and 10% by mass of the precursor of the siloxane resin including the phenyl group. The insulating paste according to the first working example including the siloxane resin in which the number of alkyl groups (herein, methyl groups) was greater than the number of phenyl groups was thereby produced.

Next, the insulating pastes according to the first to third reference examples were produced as follows:

The insulating paste according to the first reference example was produced based on a process similar to the process of producing the insulating paste according to the first working example so that the siloxane resin did not have the alkyl groups but had the phenyl groups as the substituents. In the mixing process, phenyltriphenoxysilane having undergone hydrolysis, condensation polymerization, and removal of the by-product was used as the precursor of the siloxane resin. In this case, the insulating paste according to the first reference example was produced to include 55% by mass of the siloxane resin, 30% by mass of diethyleneglycolmonobutylether, and 15% by mass of the fillers.

The insulating paste according to the second reference example was produced based on a process similar to the process of producing the insulating paste according to the first working example so that the siloxane resin had the methyl groups and the phenyl groups as the substituents, and the number of phenyl groups was greater than the number of methyl groups. Methyltrimethoxysilane and phenyltriphenoxysilane were herein used as the precursor of the siloxane resin. In the filler adding process, phenyltriphenoxysilane having undergone hydrolysis, condensation polymerization, and removal of the by-product was added to the mixed solution. In this case, the insulating paste according to the second reference example was produced so that 5% by mass of the precursor of the siloxane resin including the methyl groups and 50% by mass of the precursor of the siloxane resin including the phenyl groups were included, and the number of phenyl groups was greater than the number of methyl groups.

The insulating paste according to the third reference example was produced based on a process similar to the process of producing the insulating paste according to the first working example so that the siloxane resin did not have the phenyl groups but had the methyl groups as the substituents. In the mixing process, methyltrimethoxysilane was used as the precursor of the siloxane resin. In this case, the insulating paste according to the third reference example was produced to include 55% by mass of the siloxane resin, 30% by mass of diethyleneglycolmonobutylether, and 15% by mass of the fillers.

<5-2. Manufacture of Solar Cell Devices According to First Working Example and First to Third Reference Examples>

Next, solar cell devices were manufactured using the insulating pastes according to the first working example and the first to third reference examples.

First, a polycrystalline silicon substrate that was square in plan view, had sides each having a length of approximately 156 mm, and had a thickness of approximately 200 μm was prepared as the silicon substrate 1 including the first semiconductor layer 2 of the p-type. The silicon substrate 1 was etched with a NaOH solution to remove a damaged layer on the surface thereof. The silicon substrate 1 was then cleaned. The texture was formed on the first surface 1a side of the silicon substrate 1 by RIE.

Next, phosphorus was diffused in a surface portion on the first surface 1a side of the silicon substrate 1 by gas phase thermal diffusion using a phosphorus oxychloride (POCl₃) as the source of diffusion. The second semiconductor layer 3 of the n-type having a sheet resistance of approximately 90Ω/□ was thereby formed. In this case, the second semiconductor layer 3 formed on the side surface 1c side of the silicon substrate 1 and on the second surface 1b side of the silicon substrate 1 was removed using a nitrohydrofluoric acid solution. Phosphorus glass remaining on the first surface 1a side of the silicon substrate 1 was then removed using a hydrofluoric acid solution.

An aluminum oxide layer was then formed as the first passivation layer 9 on the entire surface of the silicon substrate 1 by ALD. The aluminum oxide layer was formed by ALD under the following conditions: The silicon substrate 1 was placed in a chamber of a layer formation apparatus, and a surface temperature of the silicon substrate 1 was maintained to be approximately 200° C. The first passivation layer 9 was then formed to have a thickness of approximately 30 nm and to include an aluminum oxide by using TMA as an aluminum material and an ozone gas as an oxidizer.

The antireflection layer 5 was then formed to include a silicon nitride layer by PECVD on the first passivation layer 9 on the first surface 1a side.

Next, the insulating pastes according to the first working example and the first to third reference examples were each applied by screen printing onto the first passivation layer 9 formed on the second surface 1b in a pattern having a plurality of openings, to thereby form protective layers 11 according to the first working example and the first to third reference examples each having a thickness of 10 μm. Each opening herein had a width (also referred to as an opening width) of 80 μm and a length (also referred to as an opening length) of 1 mm. The applied insulating pastes were dried in a drying oven at 220° C. for 10 minutes.

Then, the first metal paste was applied on the first surface 1a side in a pattern of the first electrode 6, and the second metal paste was applied on the second surface 1b side in a pattern of the second electrode 7. The third metal paste was applied on the second surface 1b side in a pattern of the third electrode 8. These metal pastes were fired at a maximum temperature of 710° C. for 10 minutes to form the third semiconductor layer 4, the first electrode 6, the second electrode 7, and the third electrode 8, to thereby form the solar cell device 10 according to the first working example and the solar cell devices according to the first to third reference examples.

<5-3. Dryness of Protective Layer and Formation of Protrusions of Third Electrode>

Five solar cell devices were manufactured for each of the solar cell device 10 according to the first working example and the solar cell devices according to the first to third reference examples to evaluate dryness of the protective layer 11 and formation of protrusions of the third electrode 8 as follows:

Dryness of the protective layer 11 was determined to be “GOOD” if no component of the protective layer 11 adhered to the finger, and was determined to be “BAD” if any component of the protective layer 11 adhered to the finger in a finger contact test performed after the insulating paste used to form the protective layer 11 was applied on the second surface 1b side of the silicon substrate 1 and dried.

As for formation of protrusions of the third electrode 8, the surface of the third electrode 8 was observed using an optical microscope after the first electrode 6, the second electrode 7, and the third electrode 8were formed by firing, and a portion of the third electrode 8 having a greater thickness than a stack of the second electrode 7 and the third electrode 8 was determined as a protrusion. Formation of protrusions was determined to be “GOOD” if no protrusions of the third electrode 8 was observed, and was determined to be “BAD” if any protrusions of the third electrode 8 were observed.

As for the solar cell device 10 according to the first working example, formation of protrusions was herein determined to be “GOOD” as protrusions were observed in none of the five solar cell devices 10. As for the solar cell device 10 according to the first working example, dryness was also determined to be “GOOD” as the protective layer 11 was more likely to be dried compared with a case where the protective layer 11 was formed using the insulating paste according to the third reference example and dried. The viscosity of the insulating paste according to the first working example was 200 Pa·s, and thus was able to be controlled to be suitable for formation of the protective layer 11 by screen printing.

On the other hand, as for each of the solar cell devices according to the first and second reference examples, formation of protrusions was determined to be “BAD” as protrusions were observed in all the five solar cell devices. That is to say, poor appearance and characteristics were caused during the manufacturing process and the like.

More protrusions of the third electrode 8were observed especially in the solar cell device according to the first reference example than in the solar cell device according to the second reference example. Due to gelation of the insulating paste, the insulating paste according to the first reference example had an extremely high viscosity of 700 Pa·s, and the insulating paste according to the second reference example also had an extremely high viscosity of 600 Pa·s. The openings in the protective layers 11 according to the first and second reference examples each had an opening width greater than a desired opening width (80 μm) by 50 μm or more. Maximum output Pm (W) of the solar cell device according to the first reference example was lower than maximum output Pm (W) of the solar cell device 10 according to the first working example by 5% on average for unknown reasons.

As for the solar cell according to the third reference example, formation of protrusions of the third electrode 8was determined to be “GOOD” as protrusions were observed in none of the five solar cell devices, but dryness was determined to be “BAD” as a component of the protective layer 11 adhered to the finger in the finger contact test after the process of drying the insulating paste, and thus reduction in dryness of the protective layer 11 was observed. The viscosity of the insulating paste according to the third reference example was able to be controlled to be 220 Pa·s.

As described above, it was confirmed that the viscosity of the insulating paste according to the first working example was able to be appropriately controlled, and the insulating paste according to the first working example was easily applied and dried.

<5-4. Analysis of Contents of Protective Layer>

In each of the solar cell device 10 according to the first working example and the solar cell device according to the third reference example, contents of the protective layer 11 were analyzed by FT-IR after removal of the third electrode 8 through etching using hydrochloric acid. The insulating paste after application was herein dried at 220° C. Contents of the insulating paste according to the first working example were also analyzed by FT-IR.

In analysis by FT-IR, the protective layer 11 according to the first working example was observed to have a peak in a wave number range around 1630 cm⁻¹, which was not observed in the insulating paste before the firing process and the protective layer 11 according to the third reference example. The peak in this wave number range corresponded to the carbon-oxygen double bond, the carbon-carbon double bond, and the carbon-nitrogen double bond. The color of the protective layer 11 according to the first working example was observed to be pale yellow through visual inspection. It was thus assumed that the protective layer 11 according to the first working example included the carbon-oxygen double bond and the carbon-carbon double bond, and included benzoquinone, which was yellowish at normal temperature. Benzoquinone was presumably generated by conversion of the phenyl group into quinone.

<5-5. Production of Insulating Pastes According to Second Working Example and Fourth Reference Example>

The insulating pastes according to the second working example and the fourth reference example were produced as follows:

The insulating paste according to the second working example was produced based on the above-mentioned process of producing the insulating paste according to the first working example by adding fillers including a silicon oxide and having surfaces not covered with dimethylpolysiloxane to the mixed solution in the filler adding process. The insulating paste according to the second working example included the siloxane resin in which the number of methyl groups was greater than the number of phenyl groups as in the insulating paste according to the first working example.

The insulating paste according to the fourth reference example was produced based on a process similar to the process of producing the insulating paste according to the second working example so that the siloxane resin had the methyl groups and the phenyl groups as the substituents, and the number of phenyl groups was greater than the number of methyl groups. Methyltrimethoxysilane and phenyltriphenoxysilane were herein used as the precursor of the siloxane resin. Specifically, in the mixing process, the mixed solution was produced to include 25% by mass of methyltrimethoxysilane as the precursor of the siloxane resin including the methyl groups, 35% by mass of water, 40% by mass of diethyleneglycolmonobutylether, and 50 ppm of hydrochloric acid. In the filler adding process, phenyltriphenoxysilane having undergone hydrolysis, condensation polymerization, and removal of the by-product was added to the mixed solution. In this case, the gross mass of the siloxane resin including the phenyl group in the insulating paste was set to 35% by mass.

<5-6. Manufacture of Solar Cell Devices According to Second Working Example and Fourth Reference Example>

Based on the above-mentioned process of manufacturing the solar cell device 10 according to the first working example, the insulating paste after application was dried at a temperature of five levels including 220° C., 230° C., 240° C., 250° C., and 260° C., and the firing process was performed at a maximum temperature of four levels including 680° C., 700° C., 720° C., and 740° C. That is to say, heat treatment was performed for each of the second working example and the fourth reference example under twenty conditions, which were combinations of the five levels of the drying temperature and the four levels of the maximum temperature in the firing process.

<5-7. Adhesion of Third Electrode>

One hundred solar cell devices 10 having been heat treated under each of the twenty conditions were manufactured as the solar cell devices 10 according to the second working example and one hundred solar cell devices having been heat treated under each of the twenty conditions were manufactured as the solar cell devices according to the fourth reference example to evaluate adhesion of the third electrode 8 as follows:

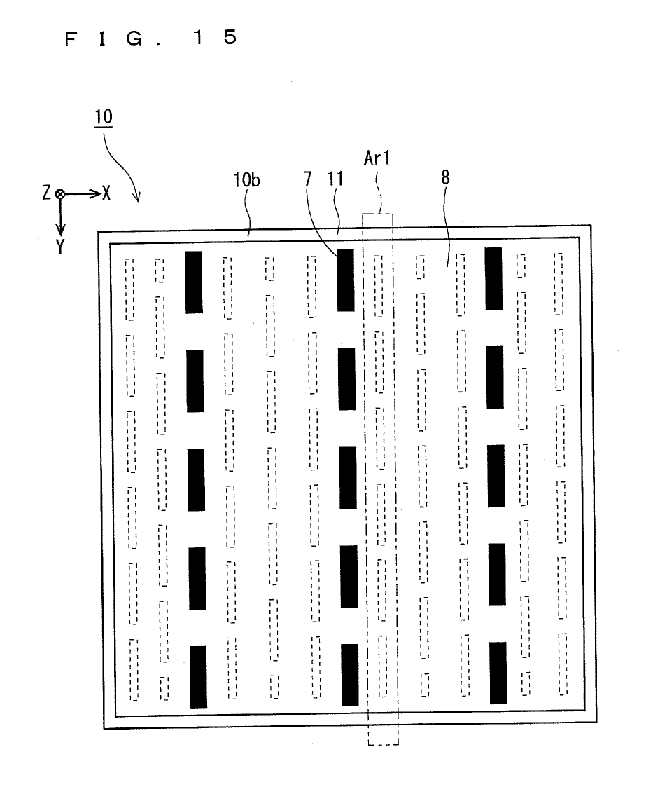

In order to evaluate adhesion of the third electrode 8, a tape was applied, for each of the solar cell devices 10 according to the second working example and the solar cell devices according to the fourth reference example, to an area Ar1 enclosed by an alternate long and two short dashes line of the second surface 10b as illustrated in FIG. 15, and was then removed to check whether the third electrode 8 was peeled. In this case, the tape had an adhesion of 3.27 N/cm², a width of 20 mm, and a length equal to or greater than the length of each side of the second surface 10b (approximately 156 mm). Adhesion was determined to be “EXCELLENT (double circle)” if peeling of the third electrode 8 was observed in none of the one hundred solar cell devices manufactured through heat treatment performed under one condition. Adhesion was determined to be “VERY GOOD (single circle)” if peeling of the third electrode 8 was observed in one or two of the one hundred solar cell devices manufactured through heat treatment performed under one condition. Adhesion was determined to be “GOOD (triangle)” if peeling of the third electrode 8 was observed in three to ten of the one hundred solar cell devices manufactured through heat treatment performed under one condition. Adhesion was determined to be “BAD (cross)” if peeling of the third electrode 8 was observed in eleven or more of the one hundred solar cell devices manufactured through heat treatment performed under one condition. The results are shown in Table 1 below.

TABLE 1

| | DRYING TEMPERATURE (° C.) | | | | | | | | | | | |
|---|---|---|---|---|---|---|---|---|---|---|---|---|
| | 220 | | | | 230 | | | | 240 | | | |
| | FIRING TEMPERATURE (° C.) | | | | | | | | | | | |
| | 680 | 700 | 720 | 740 | 680 | 700 | 720 | 740 | 680 | 700 | 720 | 740 |
| FOURTH REFERENCE | ⊚ | ⊚ | ⊚ | ⊚ | ◯ | ⊚ | ⊚ | ⊚ | Δ | ◯ | ◯ | ◯ |
| EXAMPLE | | | | | | | | | | | | |
| SECOND WORKING | ⊚ | ⊚ | ⊚ | ⊚ | ⊚ | ⊚ | ⊚ | ⊚ | ⊚ | ⊚ | ⊚ | ⊚ |
| EXAMPLE | | | | | | | | | | | | |

| | DRYING TEMPERATURE (° C.) | | | | | | | |
|---|---|---|---|---|---|---|---|---|
| | 250 | | | | 260 | | | |
| | FIRING TEMPERATURE (° C.) | | | | | | | |
| | 680 | 700 | 720 | 740 | 680 | 700 | 720 | 740 |
| FOURTH REFERENCE | X | Δ | Δ | Δ | X | X | X | X |
| EXAMPLE | | | | | | | | |
| SECOND WORKING | ⊚ | ⊚ | ⊚ | ⊚ | ◯ | ⊚ | ⊚ | ⊚ |
| EXAMPLE | | | | | | | | |

As shown in Table 1, adhesion of the third electrode 8 tended to be higher in a case where the insulating paste according to the second working example was used than in a case where the insulating paste according to the fourth reference example was used. In a case where the drying temperature was 240° C. or more, adhesion of the third electrode 8was observed to be higher in the solar cell device 10 according to the second working example than in the solar cell device according to the fourth reference example, as shown in Table 1.

<6. Others>

In the above-mentioned one embodiment, the insulating paste may be free of the plurality of fillers, for example. Such an insulating paste can be used in a case where the sizes of the openings in the protective layer 11 are not required to have strict accuracy, such as a case where the openings of the protective layer 11 have relatively large sizes.

What is claimed is:

1. An insulating paste comprising:
a siloxane resin including a phenyl group and an alkyl group expressed by a general formula CₙH₂ₙ₊₁, n being a natural number; and
an organic solvent, wherein
the number of alkyl groups is greater than the number of phenyl groups in the siloxane resin.

2. The insulating paste according to claim 1, wherein
the alkyl group includes a methyl group.

3. The insulating paste according to claim 2, wherein
the alkyl group further includes a propyl group.

4. The insulating paste according to claim 1, further comprising
a plurality of fillers.

5. The insulating paste according to claim 4, wherein
each of the fillers has a surface covered with an organic coating containing a material different from the siloxane resin.

6. The insulating paste according to claim 5, wherein
the material contained in the organic coating has a structure in which the number of carbon atoms in a main chain is six or more, or the total number of carbon atoms and silicon atoms in a main chain is six or more.

7. The insulating paste according to claim 6, wherein
the organic coating includes at least one substance selected from the group consisting of octylsilane, a dodecyl group, and dimethylpolysiloxane.

8. The insulating paste according to claim 1, being substantially free of an organic binder.

9. The insulating paste according to claim 1, further comprising
a hydrolyzable additive including a Si—O bond or a Si—N bond, and not having undergone condensation polymerization.

10. A method of manufacturing a solar cell device, comprising:
forming a passivation layer on a semiconductor substrate;
applying the insulating paste according to claim 1 onto the passivation layer; and
firing the insulating paste to thereby form a protective layer on the passivation layer.

11. A solar cell device comprising:
a semiconductor substrate including a p-type semiconductor region in a surface thereof;
a passivation layer located on the p-type semiconductor region, and including an aluminum oxide; and
a protective layer located on or above the passivation layer, and including a silicon oxide, wherein
the protective layer includes at least one double bond selected from the group consisting of a carbon-oxygen double bond, a carbon-carbon double bond, and a carbon-nitrogen double bond.

12. The solar cell device according to claim 11, wherein
the protective layer includes a Si—OH bond.

13. The solar cell device according to claim 11, further comprising
a silicon oxide layer located between the protective layer and the passivation layer, and being denser than the protective layer.

14. The solar cell device according to claim 11, wherein
the protective layer includes benzoquinone.
